(19) United States
(12) Patent Application Publication
(10) Pub. No.: US 2025/0393332 A1
(43) Pub. Date: Dec. 25, 2025

(54) IMAGE SENSOR

(71) Applicant: Samsung Electronics Co., Ltd., Suwon-si (KR)

(72) Inventors: Sooyoung KANG, Suwon-si (KR); Doyeon KIM, Suwon-si (KR); Jongeun PARK, Suwon-si (KR)

(73) Assignee: Samsung Electronics Co., Ltd., Suwon-si (KR)

(21) Appl. No.: 19/242,320

(22) Filed: Jun. 18, 2025

(30) Foreign Application Priority Data
Jun. 24, 2024 (KR) 10-2024-0081675

(51) Int. Cl. H10F 39/00

(52) U.S. Cl. CPC H10F 39/811

(57) ABSTRACT

An image sensor may include: a first structure including a first terminal, a first interlayer dielectric covering the first terminal, and a first bonding pad within the first interlayer dielectric and electrically connected to the first terminal; a second structure including a second terminal, a second interlayer dielectric contacting the second terminal, and a second bonding pad within the second interlayer dielectric and electrically connected to the second terminal; and a shield conductive pattern within one of the first interlayer dielectric and the second interlayer dielectric and electrically connected to a third terminal. The first bonding pad may be bonded to the second bonding pad, and the shield conductive pattern may include a pattern surface facing another one of the first interlayer dielectric and the second interlayer dielectric.

### CROSS-REFERENCE TO RELATED APPLICATION

This application claims priority under 35 U.S.C. § 119 to Korean Patent Application No. 10-2024-0081675, filed on Jun. 24, 2024, in the Korean Intellectual Property Office, the disclosure of which is incorporated by reference herein in its entirety.

### BACKGROUND

The present disclosure relates to an image sensor.

An image sensor is a semiconductor device converting an optical image into an electrical signal. With the recent development of the computer and communication industries, the demand for high-performance image sensors has been increasing in various fields such as digital cameras, camcorders, personal communication system (PCS), game consoles, security cameras, and medical micro-cameras. Image sensors may be classified into charge-coupled device (CCD) type and complementary metal oxide semiconductor (CMOS) type. A CMOS-type image sensor includes a plurality of pixels arranged two-dimensionally. Each of the pixels includes a photodiode (PD). The photodiode serves to convert incident light into an electrical signal.

### SUMMARY

Example embodiments provide an image sensor including shield conductive patterns selectively provided in any one of adjacent structures.

According to one or more example embodiments, an image sensor may include: a first structure including a first terminal, a first interlayer dielectric covering the first terminal, and a first bonding pad within the first interlayer dielectric and electrically connected to the first terminal; a second structure including a second terminal, a second interlayer dielectric covering the second terminal, and a second bonding pad within the second interlayer dielectric and electrically connected to the second terminal; and a shield conductive pattern within one of the first interlayer dielectric and the second interlayer dielectric and electrically connected to a third terminal. The first bonding pad may be bonded to the second bonding pad, the shield conductive pattern may include a pattern surface facing another of the first interlayer dielectric and the second interlayer dielectric, and an entirety of the pattern surface of the shield conductive pattern may contact the other of the first interlayer dielectric and the second interlayer dielectric.

According to one or more example embodiments, an image sensor may include: an intermediate structure including a first intermediate terminal, a first intermediate interlayer dielectric covering the first intermediate terminal, and a first intermediate bonding pad within the first intermediate interlayer dielectric and electrically connected to the first intermediate terminal; a peripheral circuit structure including a peripheral circuit terminal, a peripheral circuit interlayer dielectric covering the peripheral circuit terminal, and a peripheral circuit bonding pad within the peripheral circuit interlayer dielectric and electrically connected to the peripheral circuit terminal; and a lower shield conductive pattern within one of the first intermediate interlayer dielectric and the peripheral circuit interlayer dielectric and electrically connected to a lower shield terminal. The first intermediate bonding pad may be bonded to the peripheral circuit bonding pad, the lower shield conductive pattern may include a pattern surface facing another one of the first intermediate interlayer dielectric and the peripheral circuit interlayer dielectric, and an entirety of the pattern surface of the lower shield conductive pattern may contact the other of the first intermediate interlayer dielectric and the peripheral circuit interlayer dielectric.

According to one or more example embodiments, an image sensor may include: a first structure including a first terminal, a first interlayer dielectric covering the first terminal, and a first bonding pad within the first interlayer dielectric and electrically connected to the first terminal; a second structure including a second terminal, a second interlayer dielectric covering the second terminal, a second bonding pad within the second interlayer dielectric and electrically connected to the second terminal, a third interlayer dielectric, and a third bonding pad within the third interlayer dielectric; a third structure including a fourth interlayer dielectric and a fourth bonding pad within the fourth interlayer dielectric; and a shield conductive pattern within one of the first interlayer dielectric and the second interlayer dielectric and electrically connected to a third terminal. The first bonding pad may be bonded to the second bonding pad, and the third bonding pad is bonded to the fourth bonding pad, the shield conductive pattern may include a pattern surface facing another one of the first interlayer dielectric and the second interlayer dielectric, and an entirety of the pattern surface of the shield conductive pattern may contact the other one of the first interlayer dielectric and the second interlayer dielectric.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an image sensor according to one or more embodiments;

FIG. 2 is a circuit diagram of pixels included in a pixel array of an image sensor according to one or more embodiments;

FIG. 3 is a cross-sectional view of an image sensor according to one or more embodiments;

FIG. 4 is an enlarged cross-sectional view of portion ‘A’ of FIG. 3 according to one or more embodiments;

FIG. 5 is an enlarged cross-sectional view corresponding to portion ‘A’ of FIG. 3 and illustrating an image sensor according to one or more embodiments;

FIG. 6 is an enlarged cross-sectional view corresponding to portion ‘A’ of FIG. 3 and illustrating an image sensor according to one or more embodiments;

FIG. 7 is an enlarged cross-sectional view corresponding to portion ‘A’ of FIG. 3 and illustrating an image sensor according to one or more embodiments;

FIG. 8 is an enlarged cross-sectional view corresponding to portion ‘A’ of FIG. 3 and illustrating an image sensor according to one or more embodiments;

FIG. 9 is a cross-sectional view of an image sensor according to one or more embodiments;

FIG. 10 is a plan view corresponding to line I-I′ of FIG. 9 according to one or more embodiments;

FIG. 11 is a cross-sectional view of an image sensor according to one or more embodiments;

FIG. 12 is a plan view corresponding to line I-I′ of FIG. 11 according to one or more embodiments;

FIG. 13 is a cross-sectional view of an image sensor according to one or more embodiments;

FIG. 14 is a cross-sectional view of an image sensor according to one or more embodiments;

FIG. 15 is a cross-sectional view of an image sensor according to one or more embodiments;

FIG. 16 is an enlarged cross-sectional view of portion ‘B’ of FIG. 15 according to one or more embodiments;

FIG. 17 is an enlarged cross-sectional view corresponding to portion ‘B’ of FIG. 15 and illustrating an image sensor according to one or more embodiments;

FIG. 18 is a cross-sectional view of an image sensor according to one or more embodiments;

FIG. 19 is a cross-sectional view of an image sensor according to one or more embodiments;

FIG. 20 is a cross-sectional view of an image sensor according to one or more embodiments;

FIG. 21 is a cross-sectional view of an image sensor according to one or more embodiments;

FIG. 22 is a cross-sectional view of an image sensor according to one or more embodiments;

FIG. 23 is a cross-sectional view of an image sensor according to one or more embodiments;

FIG. 24 is a cross-sectional view of an image sensor according to one or more embodiments;

FIG. 25 is a cross-sectional view of an image sensor according to one or more embodiments;

FIG. 26 is a cross-sectional view of an image sensor according to one or more embodiments;

FIG. 27 is a cross-sectional view of an image sensor according to one or more embodiments;

FIG. 28A is a cross-sectional view illustrating a method of manufacturing an image sensor according to one or more embodiments;

FIG. 28B is a cross-sectional view illustrating a method of manufacturing an image sensor according to one or more embodiments;

FIG. 29A is a cross-sectional view illustrating a method of manufacturing an image sensor according to one or more embodiments;

FIG. 29B is a cross-sectional view illustrating a method of manufacturing an image sensor according to one or more embodiments;

FIG. 30 is a cross-sectional view illustrating a method of manufacturing an image sensor according to one or more embodiments;

FIG. 31A is a cross-sectional view illustrating a method of manufacturing an image sensor according to one or more embodiments;

FIG. 31B is a cross-sectional view illustrating a method of manufacturing an image sensor according to one or more embodiments;

FIG. 32 is a cross-sectional view illustrating a method of manufacturing an image sensor according to one or more embodiments;

FIG. 33 is a cross-sectional view illustrating a method of manufacturing an image sensor according to one or more embodiments;

FIG. 34 is a cross-sectional view illustrating a method of manufacturing an image sensor according to one or more embodiments;

FIG. 35A is a cross-sectional view illustrating a method of manufacturing an image sensor according to one or more embodiments;

FIG. 35B is a cross-sectional view illustrating a method of manufacturing an image sensor according to one or more embodiments;

FIG. 36A is a cross-sectional view illustrating a method of manufacturing an image sensor according to one or more embodiments;

FIG. 36B is a cross-sectional view illustrating a method of manufacturing an image sensor according to one or more embodiments;

FIG. 37 is a cross-sectional view illustrating a method of manufacturing an image sensor according to one or more embodiments;

FIG. 38A is a cross-sectional view illustrating a method of manufacturing an image sensor according to one or more embodiments;

FIG. 38B is a cross-sectional view illustrating a method of manufacturing an image sensor according to one or more embodiments;

FIG. 39 is a cross-sectional view illustrating a method of manufacturing an image sensor according to one or more embodiments;

FIG. 40 is a cross-sectional view illustrating a method of manufacturing an image sensor according to one or more embodiments;

FIG. 41 is a cross-sectional view illustrating a method of manufacturing an image sensor according to one or more embodiments;

FIG. 42A is a cross-sectional view illustrating a method of manufacturing a bonding pad according to one or more embodiments;

FIG. 42B is a cross-sectional view illustrating a method of manufacturing a bonding pad according to one or more embodiments;

FIG. 42C is a cross-sectional view illustrating a method of manufacturing a bonding pad according to one or more embodiments;

FIG. 42D is a cross-sectional view illustrating a method of manufacturing a bonding pad according to one or more embodiments;

FIG. 43A is a cross-sectional view illustrating a method of manufacturing a bonding pad according to one or more embodiments;

FIG. 43B is a cross-sectional view illustrating a method of manufacturing a bonding pad according to one or more embodiments;

FIG. 43C is a cross-sectional view illustrating a method of manufacturing a bonding pad according to one or more embodiments; and

FIG. 43D is a cross-sectional view illustrating a method of manufacturing a bonding pad according to one or more embodiments.

### DETAILED DESCRIPTION

Hereinafter, example embodiments will be described with reference to the accompanying drawings.

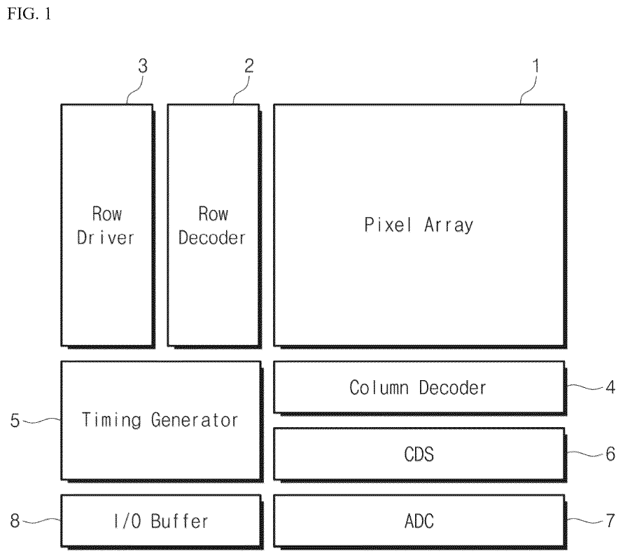

FIG. 1 is a block diagram of an image sensor according to one or more embodiments.

Referencing FIG. 1, an image sensor according to one or more embodiments may include a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may include a plurality of pixels arranged two-dimensionally, and the plurality of pixels may convert optical signals into electrical signals. The pixel array 1 may be driven by a plurality of driving signals (for example, a pixel select signal, a reset signal, and/or a charge transfer signal) transmitted from the row driver 3. The converted electrical signals may be provided to the correlated double sampler 6.

The row driver 3 may provide a plurality of driving signals for driving a plurality of pixels to the pixel array 1 based on a decoding result of the row decoder 2. When the pixels are arranged in a matrix form, the driving signals may be provided in units of rows.

The timing generator 5 may provide a timing signal and a control signal to the row decoder 2 and the column decoder 4.

The correlated double sampler 6 may receive electrical signals generated from the pixel array 1, and may hold and sample the received signals. The correlated double sampler 6 may double-sample a specific noise level and a signal level caused by an electrical signal, and may output a difference level corresponding to a difference between the noise level and the signal level.

The analog-to-digital converter 7 may convert an analog signal, corresponding to the difference level output from the correlated double sampler 6, into a digital signal and output the digital signal.

The input/output buffer 8 may latch digital signals, and may sequentially output the latched signals to an image signal processor based on a decoding result of the column decoder 4.

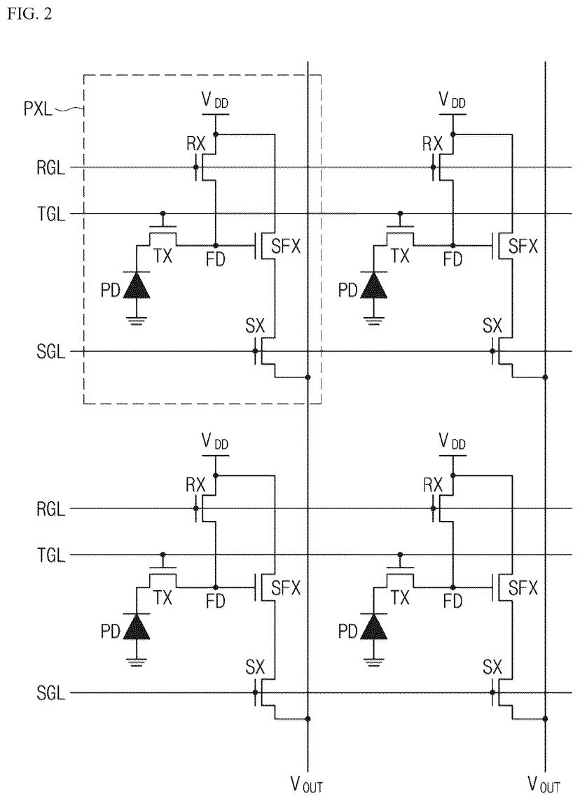

FIG. 2 is a circuit diagram of pixels included in a pixel array of an image sensor according to one or more embodiments.

Referring to FIG. 2, the pixel array may include a plurality of pixels PXL, and the pixels PXL may be arranged in a matrix form. Each of the pixels PXL may include a transfer transistor TX and logic transistors RX, SX, and SFX. The logic transistors RX, SX, and SFX may include a reset transistor RX, a select transistor SX, and a source follower transistor SFX. In addition, each of the pixels PXL may include a photoelectric conversion device PD and a floating diffusion region FD.

The photoelectric conversion device PD may generate and accumulate photoelectrons in proportion to the amount of externally incident light. The photoelectric conversion device PD may include a photodiode, a phototransistor, a photogate, a pinned photodiode, or combinations thereof. The transfer transistor TX may transfer photoelectrons, generated from the photoelectric conversion device PD, to the floating diffusion region FD. A gate of the transfer transistor TX may be connected to a transfer gate line TGL. The floating diffusion region FD may receive and cumulatively store photoelectrons generated from the photoelectric conversion device PD.

A gate of the source follower transistor SFX may be connected to the floating diffusion region FD. A drain terminal of the source follower transistor SFX may be connected to a power supply terminal V_{DD} that may be supplied with a power supply voltage. The source follower transistor SFX may be controlled based on the amount of photoelectrons accumulated in the floating diffusion region FD.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power supply terminal V_{DD}. When the reset transistor RX is turned on, the power supply voltage at the power supply terminal V_{DD} may be applied to the floating diffusion region FD through the reset transistor RX. For example, when the reset transistor RX is turned on, the charges accumulated in the floating diffusion region FD may be discharged by the power supply voltage, and the floating diffusion region FD may be reset.

The source follower transistor SFX may serve as a source follower buffer amplifier. The source follower transistor SFX may amplify a potential change in the floating diffusion region FD and output the amplified potential change to an output line V_{OUT}.

A gate of the select transistor SX may be connected to a select gate line SGL. A drain terminal of the select transistor SX may be connected to a source terminal of the source follower transistor SFX, and a source terminal of the select transistor SX may be connected to an output line V_{OUT}. The select transistors SX of pixels PXL to be read in units of rows may be selected by a select signal applied through the corresponding select gate line SGL. When the select transistor SX is turned on, the potential change amplified by the source follower transistor SFX may be output to an output line V_{OUT} through the select transistor SX.

Each of the pixels PXL includes a single photoelectric conversion device PD in FIG. 2, but one or more embodiments are not limited thereto. In some embodiments, each of the pixels PXL may include a plurality of photoelectric conversion devices PD. A plurality of transfer transistors TX may be provided in each of the pixels PXL to correspond to each of the plurality of photoelectric conversion devices PD. The plurality of photoelectric conversion devices PD and the plurality of transfer transistors TX may each constitute a plurality of sub-pixels, and the sub-pixels may share the floating diffusion region FD and the logic transistors RX, SX, and SFX of each of the pixels PXL.

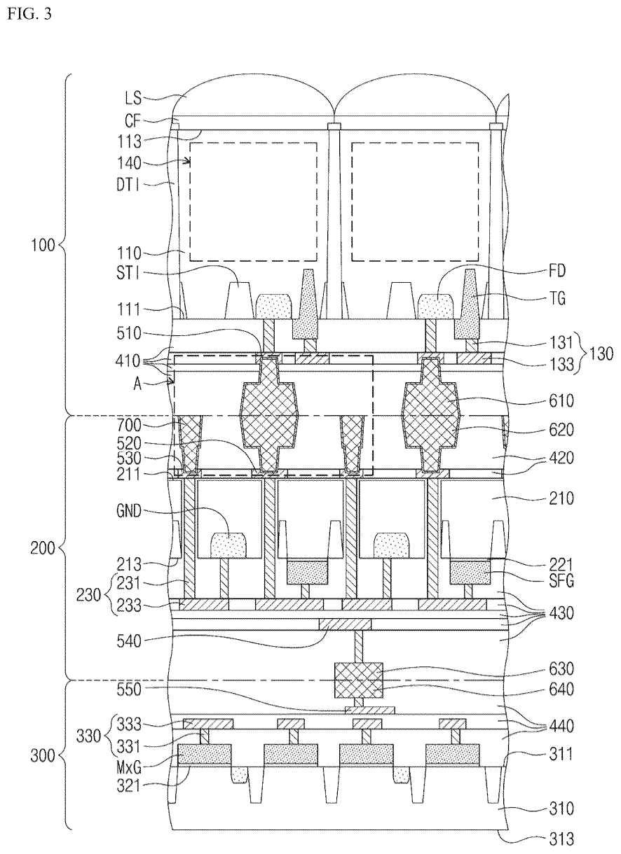

FIG. 3 is a cross-sectional view of an image sensor according to one or more embodiments.

Referring to FIG. 3, the image sensor according to one or more embodiments may include at least two structures, for example, a first structure 100, a second structure 200, and a third structure 300. The first structure 100 may be stacked on the second structure 200, and the second structure 200 may be stacked on the third structure 300. For example, the image sensor may have a stacked structure. The first structure 100 may also be referred to as a first chip, a photoelectric conversion chip, or a photoelectric conversion structure. The second structure 200 may also be referred to as a second chip, an intermediate chip, or an intermediate structure. The third structure 300 may also be referred to as a third chip, a peripheral circuit chip, or a peripheral circuit structure. The first structure 100 and the second structure 200, and the second structure 200 and the third structure 300 may be bonded to each other by at least one of various bonding methods, and may be electrically connected to each other by at least one of various connection methods.

Each of the structures may include a substrate, a device isolation pattern provided in the substrate, a gate provided on the substrate, an interlayer dielectric provided on the substrate, a contact complex provided on the substrate, and a bonding pad provided on the substrate. In addition, each of the structures may further include at least one of a terminal provided on the substrate, a shield conductive pattern provided on the substrate, and a gate insulating layer provided between the substrate and the gate. One of the structures may further include color filters CF on the substrate and microlenses LS provided on the color filters CF.

For example, the first structure 100 may include a first substrate 110, a photoelectric conversion region 140, a deep trench isolation DTI, a shallow trench isolation STI, a floating diffusion region FD, a transfer gate TG, a contact complex 130, a first interlayer dielectric 410, a first terminal 510, a first bonding pad 610, a color filter CF, and a micro lens LS. The second structure 200 may include a second substrate 210, a shallow trench isolation, a ground region GND, a select gate, a source follower gate SFG, a gate insulating layer 221, a second interlayer dielectric 420, a contact complex 230, a third interlayer dielectric 430, a second terminal 520, a third terminal 530, a fourth terminal 540, a second bonding pad 620, a third bonding pad 630, and a shield conductive pattern 700. The third structure 300 may include a third substrate 310, a shallow trench isolation, peripheral circuit gates MxG, a fourth interlayer dielectric 440, a contact complex 330, a fifth terminal 550, and a fourth bonding pad 640.

Each of the substrates 110, 210, and 310 may be a silicon (Si) substrate, a germanium (Ge) substrate, a silicon-germanium (Si—Ge) substrate, a II-VI group compound semiconductor substrate, a III-V group compound semiconductor substrate, or a silicon-on-insulator (SOI) substrate. The substrates 110, 210, and 310 may include first-type dopants, and thus may have a first conductivity type. For example, the first-type dopants may be group III elements. For example, the first-type dopants may include P-type dopants such as aluminum (Al), boron (B), indium (In), and/or gallium (Ga).

In the present specification, the first substrate 110 may be referred to as a photoelectric conversion substrate 110, the second substrate 210 may be referred to as an intermediate substrate 210, and the third substrate 310 may be referred to as a peripheral circuit substrate 310.

The photoelectric conversion regions 140 may include dopants having a second conductivity type, different from the first conductivity type, and thus may have the second conductivity type. For example, the second-type dopants may be group V elements. For example, the second-type dopants may include n-type dopants such as phosphorus, arsenic, bismuth, and/or antimony.

A P-N junction may be formed between the first substrate 110 and the photoelectric conversion regions 140, resulting in the photoelectric conversion devices PD.

Each of the substrates 110, 210, and 310 may have one surface and an opposite surface. The one surface may be a front surface of each of the substrates 110, 210, and 310, and the opposite surface may be a rear surface of each of the substrates 110, 210, and 310. Conversely, the one surface may be a rear surface of each of the substrates 110, 210, and 310, and the opposite surface may be a front surface of each of the substrates 110, 210, and 310. For example, the first substrate 110 may have a first surface 111 and a second surface 113 opposing the first surface 111. The first surface 111 may be a front surface of the first substrate 110, and the second surface 113 may be a rear surface of the first substrate 110. Light may be incident on the second surface 113 of the first substrate 110. For example, the second surface 113 of the first substrate 110 may be a light incident surface. The second substrate 210 may have a third surface 211 and a fourth surface 213 opposing the third surface 211. The third substrate 310 may have a fifth surface 311 and a sixth surface 313 opposing the fifth surface 311.

A deep trench isolation pattern DTI may be provided in the first substrate 110 to define a plurality of pixel regions in the first substrate 110, and the photoelectric conversion regions 140 may be provided in each of the pixel regions. A shallow trench isolation pattern STI may be provided in the first substrate 110 and may be adjacent to the first surface 111 of the first substrate 110. The shallow trench isolation pattern STI may define active regions in the pixel regions.

The deep trench isolation pattern DTI may be formed in the first substrate 110 to surround each of the pixel regions in plan view. For example, the deep trench isolation DTI may be formed by a technique of filling a deep trench, formed by patterning the first substrate 110, with an insulating material (for example, a deep trench isolation (DTI) technique). The pixel region may be a portion of the first substrate 110, surrounded by the deep trench isolation pattern DTI.

The deep trench isolation pattern DTI may penetrate through the first substrate 110. For example, the deep trench isolation pattern DTI may penetrate through the first and second surfaces 111 and 113 of the first substrate 110 and a substrate body between the first and second surfaces 111 and 113 of the first substrate 110.

In one or more embodiments, the deep trench isolation pattern DTI may include a conductive isolating layer, provided in a deep trench, and an insulating liner provided between the first substrate 110 and the conductive isolating layer. The conductive isolating layer may include a conductive material such as a doped semiconductor material (for example, doped polysilicon). The conductive isolating layer may be spaced apart from the first substrate 110 by an insulating liner to be electrically isolated from the first substrate 110 during the operation of an image sensor.

The shallow trench isolation pattern STI may be disposed in a shallow trench recessed from the first surface 111 of the first substrate 110 by a specific depth. For example, the shallow trench isolation pattern STI may be formed by a technique of filling a shallow trench with an insulating material (for example, a shallow trench isolation (STI) technique), and may not penetrate through the first substrate 110. The shallow trench isolation pattern STI may include a silicon oxide, a silicon nitride, a silicon oxynitride, or combinations thereof, but one or more embodiments are not limited thereto.

In one or more embodiments, the shallow trench isolation pattern STI may define active regions spaced apart from each other. For example, the shallow trench isolation pattern STI may be provided between the active regions to electrically isolate the active regions from each other.

In one or more embodiments, the deep trench isolation pattern DTI may partially overlap the shallow trench isolation pattern STI. The overlapping portion of the deep trench isolation pattern DTI and the shallow trench isolation pattern STI may correspond to a portion of the shallow trench isolation pattern STI or a portion of the deep trench isolation pattern DTI.

The transfer gate TG may be disposed on the first surface 111 of the first substrate 110. The transfer gate TG may be disposed on a corresponding active region of each of the pixel regions. A gate insulating layer may be disposed between the transfer gate TG and the corresponding active region. In one or more embodiments, a gate trench may be formed in the corresponding active region, and the transfer gate TG may fill the gate trench. The gate insulating layer may extend to be disposed between the transfer gate TG and the inner surface of the gate trench. A transfer transistor including the transfer gate TG may be a vertical channel transistor. The transfer gate TG may be provided as a single electrode in each pixel, but one or more embodiments are not limited thereto. In one or more embodiments, the transfer gate TG may also be provided as a pair of electrodes spaced from each other in each pixel. The floating diffusion region FD may be provided in the corresponding active region on one side of the transfer gate TG.

A shallow trench isolation pattern of the second structure 200 may be provided in the second substrate 210 to define active regions. A shallow trench isolation pattern of the second structure 200 may be adjacent to the fourth surface 213 of the second substrate 210. A select gate and a source follower gate SFG may be disposed on the fourth surface 213 of the second substrate 210. For example, the select gate and the source follower gate SFG may be disposed on corresponding active regions of the second substrate 210. The gate insulating layer 221 may be disposed between the source follower gate SFG and a corresponding active region and between the select gate and a corresponding active region. Source/drain regions may be disposed in corresponding active regions on opposite sides adjacent to the respective gates SFG. In one or more embodiments, ground regions GND may be disposed in corresponding active regions, among the active regions of the second substrate 210, respectively. In one or more embodiments, the ground region GND may receive a ground voltage.

A shallow trench isolation pattern of the third structure 300 may define active regions in the third substrate 310. The shallow trench isolation pattern of the third structure 300 may be adjacent to the fifth surface 311 of the third substrate 310. Peripheral circuit gates MxG may be disposed on the active regions of the third substrate 310 with a gate insulating layer 321 interposed therebetween.

The first interlayer dielectric 410 may be disposed on the first surface 111 of the first substrate 110 to cover the first surface 111 and the transfer gate TG. The first interlayer dielectric 410 may also be referred to as a photoelectric conversion interlayer dielectric. The first interlayer dielectric 410 may be provided in plural. The plurality of first interlayer dielectrics 410 may be sequentially stacked on the first surface 111 of the first substrate 110. The second interlayer dielectric 420 may be disposed on the third surface 211 of the second substrate 210 to cover the third surface 211 of the second substrate 210. The second interlayer dielectric 420 may also be referred to as a second intermediate interlayer dielectric. The second interlayer dielectric 420 may be provided in plural. The plurality of second interlayer dielectrics 420 may be sequentially stacked on the third surface 211 of the second substrate 210. The third interlayer dielectric 430 may be disposed on the fourth surface 213 of the second substrate 210 to cover the fourth surface 213, the source follower gate SFG, and other gates. The third interlayer dielectric 430 may also be referred to as a first intermediate interlayer dielectric. The third interlayer dielectric 430 may be provided in plural. The plurality of third interlayer dielectrics 430 may be sequentially stacked on the fourth surface 213 of the second substrate 210. The fourth interlayer dielectric 440 may be disposed on the fifth surface 311 of the third substrate 310 to cover the fifth surface 311 and the peripheral circuit gates MxG. The fourth interlayer dielectric 440 may also be referred to as a peripheral circuit interlayer dielectric. The fourth interlayer dielectric 440 may be provided in plural. The plurality of fourth interlayer dielectrics 440 may be sequentially stacked on the fifth surface 311 of the third substrate 310.

The contact complexes 130, 230, and 330 may include contact plugs 131, 231, and 331 and contact interconnections 133, 233, and 333. The contact plugs 131, 231, and 331 and the contact interconnections 133, 233, and 333 may be disposed in the interlayer dielectrics 410, 420, 430, and 440. The contact interconnections 133, 233, and 333 may include gate lines TGL, RGL, and SGL (see FIG. 2), a power supply voltage line V_{DD} (see FIG. 2), an output line V_{OUT} (see FIG. 2), a ground voltage line, a local connection line, or the like. The contact plugs 131, 231, and 331 and the contact interconnections 133, 233, and 333 may electrically connect gates, terminals, and impurity regions (for example, floating diffusion regions FD, source/drain regions, and ground regions GND) to form desired circuits (for example, a pixel circuit and/or a peripheral circuit).

The gates TG, SFG, and MxG may include a conductive material (for example, doped polysilicon, metal, conductive metal nitride, metal silicide, or the like). The gate insulating layers 221 and 321 may include an insulating material (for example, a silicon oxide, a silicon nitride, a silicon oxynitride, a high-dielectric). In one or more embodiments, gate spacers may be provided on opposite side surfaces of each of the gates TG, SFG, and MxG. The gate spacers may include an insulating material (for example, a silicon oxide, a silicon nitride, and/or a silicon oxynitride).

In one or more embodiments, the transfer gate TG may be electrically connected to a corresponding contact interconnection 133 through a contact plug 131 provided on the transfer gate TG. The source follower gate SFG may be electrically connected to a corresponding contact interconnection 233 through a contact plug 231 provided on the source follower gate SFG. The ground region GND may be electrically connected to a corresponding contact interconnection 233 through a contact plug 231 provided on the ground region GND. The peripheral circuit gate MxG may be electrically connected to a corresponding contact interconnection 333 through a contact plug 331 provided on the peripheral circuit gate MxG.

Each of the terminals 510, 520, 530, 540, and 550 may be disposed between corresponding interlayer dielectrics. For example, the first terminal 510 may be disposed between the first interlayer dielectrics 410, the second terminal 520 and the third terminal 530 may be disposed between the second interlayer dielectrics 420, the fourth terminal 540 may be disposed between the third interlayer dielectrics 430, and the fifth terminal 550 may be disposed between the fourth interlayer dielectrics 440. In one or more embodiments, the terminal includes one surface and an opposite surface. The one surface of the terminal may be electrically connected to a bonding pad or a shield conductive pattern, and the opposite surface of the terminal may be electrically connected to a contact plug.

For example, the floating diffusion region FD may be electrically connected to a corresponding first terminal 510 through a contact plug 131 provided on the floating diffusion region FD. The source follower gate SFG may be electrically connected to a corresponding second terminal 520 through a contact plug 231 and/or a contact interconnection 233 provided on the source follower gate SFG. The ground region GND may be electrically connected to a corresponding third terminal 530 through a contact plug 231 and/or a contact interconnection 233 provided on the ground region GND.

In the present specification, the first terminal 510 may be referred to as a photoelectric conversion terminal, the second terminal 520 may be referred to as a second intermediate terminal, the third terminal 530 may be referred to as a shield terminal or an upper shield terminal, the fourth terminal 540 may be referred to as a first intermediate terminal, and the fifth terminal 550 may be referred to as a peripheral circuit terminal.

The first bonding pad 610 may be disposed in a lowermost first interlayer dielectric 410, the second bonding pad 620 may be disposed in an uppermost second interlayer dielectric 420, the third bonding pad 630 may be disposed in a lowermost third interlayer dielectric 430, and the fourth bonding pad 640 may be disposed in an uppermost fourth interlayer dielectric 440.

In one or more embodiments, the first bonding pad 610 may be electrically connected to the first terminal 510, the second bonding pad 620 may be electrically connected to the second terminal 520, the third bonding pad 630 may be electrically connected to the fourth terminal 540, and the fourth bonding pad 640 may be electrically connected to the fifth terminal 550.

The bonding pads 610, 620, 630, and 640 may electrically connect the structures 100, 200, and 300. In one or more embodiments, the first bonding pad 610 and the second bonding pad 620 may be bonded together to electrically connect the first structure 100 to the second structure 200.

For example, the floating diffusion region FD of the first structure 100 may be electrically connected to the source follower gate SFG of the second structure 200 through the contact plug 131, the first terminal 510, the first bonding pad 610, the second bonding pad 620, the second terminal 520, the contact plug 231 penetrating through the second substrate 210, the contact interconnection 233, and the contact plug 231 connected to the source follower gate SFG.

In one or more embodiments, the third bonding pad 630 and the fourth bonding pad 640 may be bonded together to electrically connect the second structure 200 to the third structure 300.

For example, the fourth terminal 540 of the second structure 200 may be electrically connected to the fifth terminal 550 of the third structure 300 through the third bonding pad 630 and the fourth bonding pad 640.

In one or more embodiments, the first to fourth bonding pads 610, 620, 630, and 640 may include copper. The first and second bonding pads 610 and 620 may be bonded to each other by a copper-to-copper bonding technique, and the third and fourth bonding pads 630 and 640 may be bonded to each other by a copper-to-copper bonding technique. The bonded bonding pads 610 and 620, or 630 and 640 may be integrated with each other without a boundary therebetween. In addition, a portion of the interlayer dielectrics 410, 420, 430, and 440 may be covalently bonded.

In one or more embodiments, the first and second bonding pads 610 and 620 may vertically overlap each of the pixel regions.

In the present specification, the first bonding pad 610 may be referred to as a photoelectric conversion bonding pad, the second bonding pad 620 may be referred to as a second intermediate bonding pad, the third bonding pad 630 may be referred to as a first intermediate bonding pad, and the fourth bonding pad 640 may be referred to as a peripheral circuit bonding pad.

In one or more embodiments, the shield conductive pattern 700 may be disposed in an uppermost second interlayer dielectric 420. In one or more embodiments, the shield conductive pattern 700 may have a pattern surface directed toward the first interlayer dielectric 410, and the entire pattern surface of the shield conductive pattern 700 may be in contact with the first interlayer dielectric 410 (for example, a lowermost first interlayer dielectric 410). In one or more embodiments, the shield conductive pattern 700 may be electrically connected to a terminal. For example, the shield conductive pattern 700 may be electrically connected to the third terminal 530.

In one or more embodiments, the shield conductive pattern 700 may be electrically connected to a ground region GND and provided between bonding pads of adjacent pixels to block electrical coupling (for example, parasitic capacitance) between the bonding pads. For example, the shield conductive pattern 700 may be provided between the second bonding pad 620 of one pixel and the second bonding pad 620 of another pixel adjacent to the one pixel to block electrical coupling (for example, parasitic capacitance) between the second bonding pad of the one pixel and the second bonding pad of the adjacent pixel.

In one or more embodiments, the shield conductive pattern 700 may vertically overlap each of the pixel regions.

A substrate insulating layer may be provided on the second surface 113 of the first substrate 110. The substrate insulating layer may cover the second surface 113 of the first substrate 110 and may have a single-layer structure or a multilayer structure. In one or more embodiments, the substrate insulating layer may include a silicon-based insulating material (for example, a silicon compound, a silicon nitride, and/or a silicon oxynitride) and/or an insulating metal oxide.

Color filters CF may be provided on the substrate insulating layer. In one or more embodiments, as illustrated in the drawing, the color filters CF may be disposed on the second surface 113 of the first substrate 110 to correspond to each of the pixels. In one or more embodiments, each of the color filters CF may vertically overlap a corresponding one of the photoelectric conversion regions 140. However, one or more embodiments are not limited thereto. In some embodiments, each of the color filters CF may vertically overlap a plurality of adjacent photoelectric conversion regions 140. Photoelectric conversion regions 140, respectively corresponding to the color filters CF, may be arranged in a matrix form. For example, the corresponding photoelectric conversion regions 140 may be arranged in a 2×2 matrix form, a 3×3 matrix form, or a 4×4 matrix form. In some embodiments, the color filters CF may include a first color filter having a first color, a second color filter having a second color, and a third color filter having a third color. In one or more embodiments, the first color may be one of red, green, and blue, the second color may be another one of red, green, and blue, and the third color may be the remaining one of red, green, and blue. Alternatively, the first color may be one of magenta, cyan, and yellow, the second color may be another one of magenta, cyan, and yellow, and the third color may be the remaining one of magenta, cyan, and yellow. However, one or more embodiments are not limited thereto. The first to third colors may be a variety of other colors.

Microlenses LS may be disposed on the second surface 113 of the first substrate 110. For example, the microlenses LS may be disposed on the color filters CF. As illustrated in FIG. 3, the microlenses LS may vertically overlap each of the photoelectric conversion regions 140. Alternatively, each of the microlenses LS may vertically overlap the plurality of adjacent photoelectric conversion regions 140. For example, each of the microlenses LS may vertically overlap the photoelectric conversion regions 140 arranged in a 2×2 matrix form, a 3×3 matrix form, or a 4×4 matrix form. In some embodiments, the number of photoelectric conversion regions 140 overlapping at least one of the microlenses LS may be different from the number of photoelectric conversion regions 140 overlapping at least another one of the microlenses LS. For example, the at least one microlens LS may vertically overlap a pair of adjacent photoelectric conversion regions 140, and the at least another microlens LS may vertically overlap a single photoelectric conversion region 140 or four or more adjacent photoelectric conversion regions 140.

Each of the microlenses LS may have an upwardly convex shape in cross-sectional view. In some embodiments, each of the microlenses LS may have a circular or elliptical shape in plan view. The microlenses LS may be formed of a light-transmitting resin.

In one or more embodiments, the microlens LS may include a lens pattern and a planarization portion. The planarization portion of the microlens LS may be provided on the color filter CF, and the lens pattern may be provided on the planarization portion. The lens pattern and the planarization portion may be integrated with each other without a boundary therebetween. The lens pattern may include the same material as the planarization portion. In one or more embodiments, the planarization portion may be omitted, and the lens pattern may be directly disposed on the color filter CF.

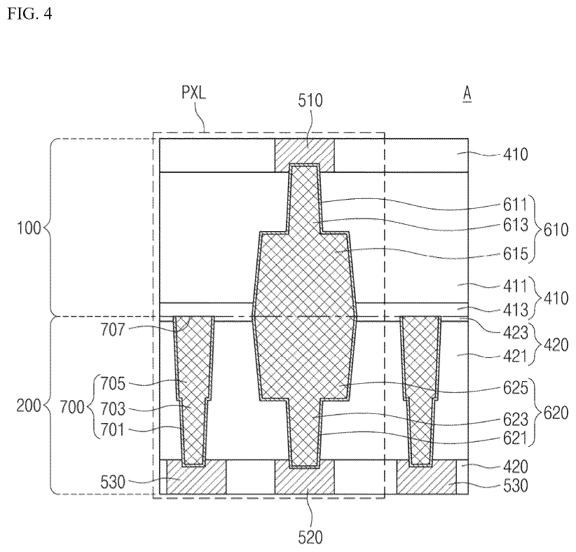

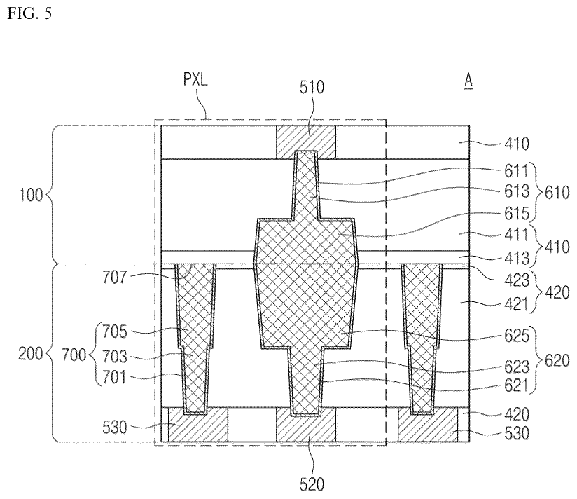

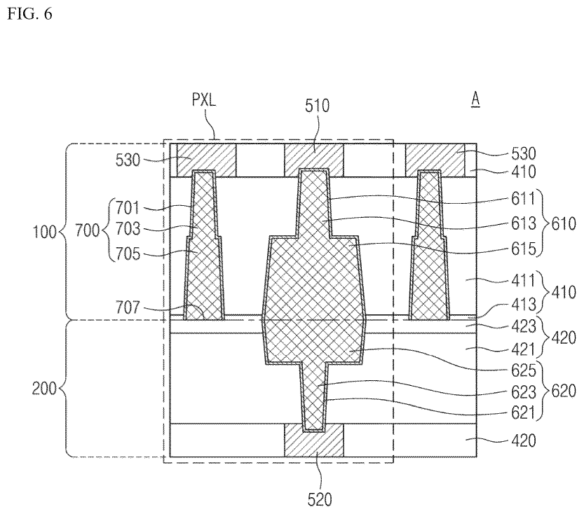

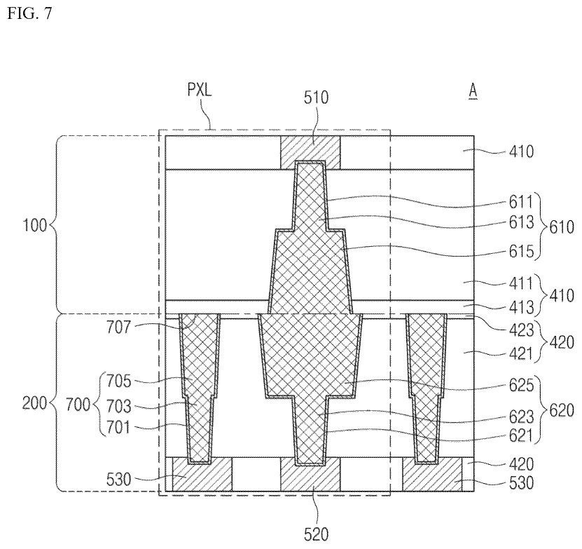

FIG. 4 is an enlarged cross-sectional view of portion ‘A’ of FIG. 3. FIG. 5 is an enlarged cross-sectional view corresponding to portion ‘A’ of FIG. 3 and illustrating an image sensor according to one or more embodiments. FIG. 6 is an enlarged cross-sectional view corresponding to portion ‘A’ of FIG. 3 and illustrating an image sensor according to one or more embodiments. FIG. 7 is an enlarged cross-sectional view corresponding to portion ‘A’ of FIG. 3 and illustrating an image sensor according to one or more embodiments. FIG. 8 is an enlarged cross-sectional view corresponding to portion ‘A’ of FIG. 3 and illustrating an image sensor according to one or more embodiments. Hereinafter, redundant descriptions will be omitted to avoid repetition.

Referring to FIG. 4, the first structure 100 may include first interlayer dielectrics 410, a first terminal 510 provided in one of the first interlayer dielectrics 410, and a first bonding pad 610 provided in another of the first interlayer dielectrics 410. The another of the first interlayer dielectrics 410, in which the first bonding pad 610 is provided, may be the lowermost first interlayer dielectric 410. The second structure 200 may include second interlayer dielectrics 420, a second terminal and a third terminal 520 and 530 provided in one of the second interlayer dielectrics 420, a second bonding pad 620 provided in another of the second interlayer dielectrics 420, and a shield conductive pattern 700 provided in the another of the second interlayer dielectrics 420. The another of the second interlayer dielectrics 420 may be an uppermost second interlayer dielectric 420.

In one or more embodiments, the lowest or uppermost interlayer dielectric may include a body portion, including a first insulating material, and a capping portion including a second insulating material. The capping portion may be provided on an upper or lower surface of the body portion and may be formed of the same material as, or a material different from, a material of the body portion. For example, the lowermost first interlayer dielectric 410 may include a body portion 411, and a capping portion 413 on a lower surface of the body portion 411. The uppermost second interlayer dielectric 420 may include a body portion 421, and a capping portion 423 on an upper surface of the body portion 421. The capping portion 413 of the lowermost first interlayer dielectric 410 may be in contact with the capping portion 423 of the uppermost second interlayer dielectric 420. According to one or more embodiments, each of the other first and second interlayer dielectrics 410 and 420 may also include a body portion and a capping portion.

For example, the first insulating material of the body portions 411 and 421 may be a silicon oxide, and the second insulating material of the capping portions 413 and 423 may be at least one of a silicon oxide (SiO), a silicon nitride (SiN), a silicon oxynitride (SiON), or a silicon carbonitride (SiCN).

In one or more embodiments, the bonding pad may include a pad via portion provided adjacent to a terminal within the interlayer dielectric, a pad portion provided on the pad via portion, and a conductive liner covering external surfaces of the pad via portion and the pad portion and contacting the terminal. The pad via portion and the pad portion may be vertically aligned. The pad via portion and the pad portion may be in contact with each other to be integrated with each other without a boundary therebetween. The conductive liner may not be provided on the upper or lower surface of the pad portion. The conductive liner may serve as a seed layer and/or a diffusion barrier layer. The pad via portion may have a smaller width than the pad portion. In one or more embodiments, the pad via portion may have a width increasing in a direction away from the terminal. The pad portion may have a width increasing in a direction away from the pad via portion. A maximum width of the pad via portion may be smaller than a maximum width of the pad portion.

For example, the first bonding pad 610 may include a first pad via portion 613 provided adjacent to the first terminal 510 within the lowest first interlayer dielectric 410, a first pad portion 615 provided below the first pad via portion 613, and a first conductive liner 611 covering the external surfaces of the first pad via portion 613 and the first pad portion 615 and contacting the first terminal 510.

For example, the second bonding pad 620 may include a second pad via portion 623 provided adjacent to the second terminal 520 within the uppermost second interlayer dielectric 420, a second pad portion 625 provided on the second pad via portion 623, and a second conductive liner 621 covering (or contacting) the external surfaces of the second pad via portion 623 and the second pad portion 625 and contacting the second terminal 520.

In one or more embodiments, the shield conductive pattern 700 may include a pattern via portion 703 provided adjacent to the third terminal 530 within the uppermost second interlayer dielectric 420, a pattern portion 705 provided on the pattern via portion 703, and a pattern conductive liner 701 covering (or contacting) external surfaces of the pattern via portion 703 and the pattern portion 705 and contacting the third terminal 530. The pattern via portion 703 and the pattern portion 705 may be vertically aligned and may be in contact with each other to be integrated with each other without a boundary therebetween. The pattern conductive liner 701 may not be provided on an upper surface of the pattern portion 705. The pattern conductive liner 701 may serve as a seed layer and/or a diffusion barrier layer. The pattern via portion 703 may have a smaller width than the pattern portion 705. In one or more embodiments, the pattern via portion 703 may have a width increasing in a direction away from the third terminal 530, and the pattern portion 705 may have a width increasing in a direction away from the pattern via portion 703. A maximum width of the pattern via portion 703 may be smaller than a minimum width of the pattern portion 705.

In an image sensor according to one or more embodiments, shield conductive patterns may be selectively provided in any one of the adjacent structures to reduce a pattern density of bonding pads and improve a conversion gain.

Referring to FIG. 5, in one or more embodiments, the first bonding pad 610 may have a smaller thickness or height than the second bonding pad 620. For example, the pad portion 615 of the first bonding pad 610 may have a smaller thickness than the pad portion 625 of the second bonding pad 620. In addition, the pad via portion 613 of the first bonding pad 610 may have a smaller thickness than the pad via portion 623 of the second bonding pad 620. In FIG. 5, the pad portion 615 of the first bonding pad 610 has a smaller thickness than the pad portion 625 of the second bonding pad 620, and the pad via portion 613 of the first bonding pad 610 has substantially the same thickness as the pad via portion 623 of the second bonding pad 620. However, one or more embodiments are not limited thereto. The above-described thickness differences may be selectively applied to at least one of the pad portion and the pad via portion.

In an image sensor according to one embodiment, shield conductive patterns may be selectively provided in any one of the adjacent structures, and electrical coupling between adjacent bonding pads (for example, electrical coupling between floating diffusion regions FD) may be reduced or significantly reduced by adjusting a thickness of a bonding pad within the another structure, in which the shield conductive patterns are not included, to be a small value. In addition, reducing the pattern density of the bonding pads may decrease parasitic capacitance and improve conversion gain.

Referring to FIG. 6, the first structure 100 may include first interlayer dielectrics 410, a first terminal and a third terminal 510 and 530 provided in one of the first interlayer dielectrics 410, a first bonding pad 610 provided in another of the first interlayer dielectrics 410, and a shield conductive pattern 700 provided in the another of the first interlayer dielectrics 410. The another of the first interlayer dielectrics 410 may be a lowermost first interlayer dielectric 410. The second structure 200 may include second interlayer dielectrics 420, a second terminal 520 provided in one of the second interlayer dielectrics 420, and a second bonding pad 620 provided in another of the second interlayer dielectrics 420. The another of the second interlayer dielectrics 420 may be an uppermost second interlayer dielectric 420. In the above-described embodiment of FIG. 4, the third terminal 530 and the shield conductive pattern 700 may be provided in the second structure 200. Alternatively, in the example embodiment of FIG. 6, the third terminal 530 and the shield conductive pattern 700 may be provided in the first structure 100.

In one or more embodiments, the shield conductive pattern 700 may include a pattern via portion 703 provided adjacent to the third terminal 530 within the lowermost first interlayer dielectric 410, a pattern portion 705 provided below the pattern via portion 703, and a pattern conductive liner 701 covering the outer surfaces of the pattern via portion 703 and the pattern portion 705 and contacting the third terminal 530. The pattern conductive liner 701 may not be provided on an upper surface of the pattern portion 705.

In one or more embodiments, the second bonding pad 620 may have a smaller thickness (or height) than the first bonding pad 610. For example, the pad portion 625 of the second bonding pad 620 may have a smaller thickness than the pad portion 615 of the first bonding pad 610. Also, the pad via portion 623 of the second bonding pad 620 may have a smaller thickness than the pad via portion 613 of the first bonding pad 610. The above-described thickness differences may be selectively applied to at least one of the thickness of the pad portion and the thickness of the pad via portion.

Referring to FIGS. 5 and 6, in one or more embodiments, the bonding pad may have a thickness varying depending on the presence of the shield conductive pattern 700. As illustrated in FIG. 5, when the shield conductive pattern 700 is provided in the second interlayer dielectric 420, the second bonding pad 620 provided in the second interlayer dielectric 420 may have a larger thickness than the first bonding pad 610. For example, the first bonding pad 610 may have a smaller thickness than the second bonding pad 620. As illustrated in FIG. 6, when the shield conductive pattern 700 is provided in the first interlayer dielectric 410, the first bonding pad 610 provided in the first interlayer dielectric 410 may have larger a thickness than the second bonding pad 620. For example, the second bonding pad 620 may have a smaller thickness than the first bonding pad 610. In addition, the shield conductive pattern 700 may be provided in one of the first and second interlayer dielectrics 410 and 420, and the shield conductive pattern 700 may have a pattern surface 707 directed toward the another of the first and second interlayer dielectrics 410 and 420, and the entire pattern surface 707 of the shield conductive pattern 700 may be in contact with the another of the first and second interlayer dielectrics 410 and 420.

Referring to FIG. 7, in one or more embodiments, the first bonding pad 610 may have a smaller width than the second bonding pad 620. For example, the pad portion 615 of the first bonding pad 610 may have a smaller width than the pad portion 625 of the second bonding pad 620. Also, the pad via portion 613 of the first bonding pad 610 may have a smaller width than the pad via portion 623 of the second bonding pad 620. In FIG. 7, the pad portion 615 of the first bonding pad 610 is illustrated as having a smaller width than the pad portion 625 of the second bonding pad 620, and the pad via portion 613 of the first bonding pad 610 is illustrated as having a smaller width than the pad via portion 623 of the second bonding pad 620, but the above-described relative width difference may be selectively applied to at least one of the width of the pad portion and the width of the pad via portion.

The features of the embodiment of FIG. 7 may be applied to the embodiment of FIG. 6. For example, a first structure 100 may include a third terminal 530 and a shield conductive pattern 700, and a second bonding pad 620 may have a smaller width than a first bonding pad 610. For example, a pad portion 625 of the second bonding pad 620 may have a smaller width than a pad portion 615 of the first bonding pad 610. In addition, a pad via portion 623 of the second bonding pad 620 may have a smaller width than a pad via portion 613 of the first bonding pad 610. The above-described relative width difference may be selectively applied to at least one of a width of a pad portion and a width of a pad via portion.

Referring to FIGS. 5 to 7, in one or more embodiments, the bonding pad may have a width varying depending on the presence of the shield conductive pattern 700, similarly to the thickness of the bonding pad of FIGS. 5 and 6. As illustrated in FIG. 7, when the shield conductive pattern 700 is provided in the second interlayer dielectric 420, the second bonding pad 620 provided in the second interlayer dielectric 420 may have a larger width than the first bonding pad 610. For example, the first bonding pad 610 may have a smaller width than the second bonding pad 620. When the shield conductive pattern 700 is provided in the first interlayer dielectric 410, the first bonding pad 610 provided in the first interlayer dielectric 410 may have a larger width than the second bonding pad 620. For example, the second bonding pad 620 may have a smaller width than the first bonding pad 610.

Referring to FIG. 8, the one or more embodiments of FIGS. 5 and 7 may be applied simultaneously. For example, the first bonding pad 610 may have smaller thickness and width than the second bonding pad 620. As disclosed above, the bonding pad according to one or more embodiments may have a thickness and a width varying depending on the presence of the shield conductive pattern 700, similarly to the thickness of the bonding pads in FIGS. 5 and 6 and the width of the bonding pads in FIG. 7. As illustrated in FIG. 8, when the shield conductive pattern 700 is provided in the second interlayer dielectric 420, the second bonding pad 620 provided in the second interlayer dielectric 420 may have larger thickness and width than the first bonding pad 610. For example, the first bonding pad 610 may have smaller thickness and width than the second bonding pad 620. When the shield conductive pattern 700 is provided in the first interlayer dielectric 410, the first bonding pad 610 provided in the first interlayer dielectric 410 may have larger thickness and width than the second bonding pad 620. For example, the second bonding pad 620 may have smaller thickness and width than the first bonding pad 610. For example, the bonding pad provided in the same interlayer dielectric as the shield conductive pattern may have larger thickness and width than other bonding pads.

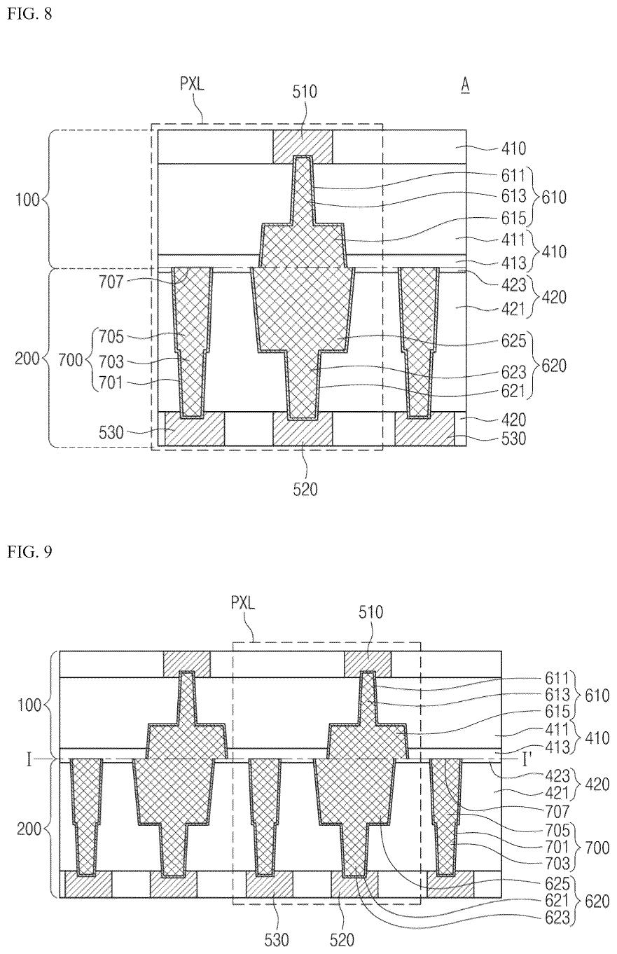

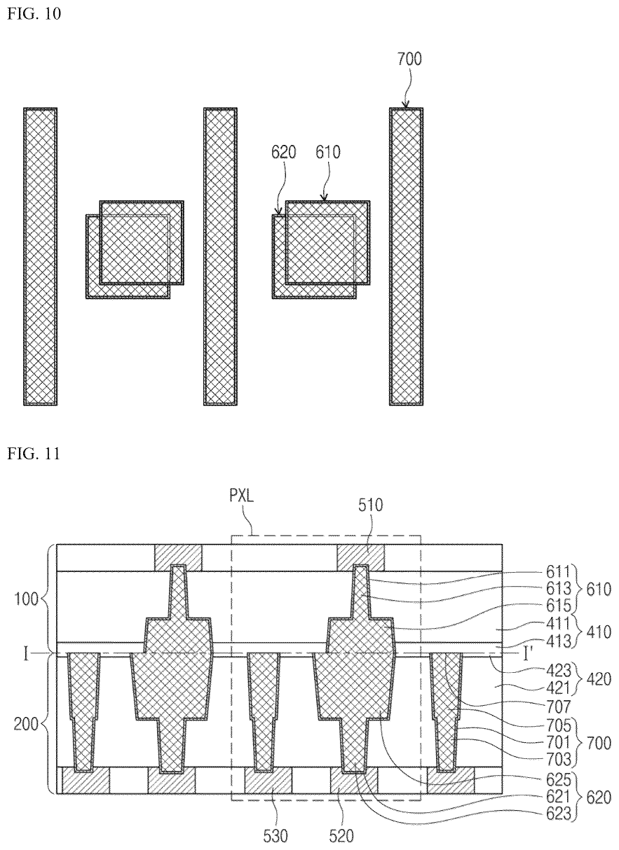

FIG. 9 is a cross-sectional view of an image sensor according to one or more embodiments, and FIG. 10 is a plan view corresponding to line I-I′ of FIG. 9. For example, FIG. 9 is a cross-sectional view of an image sensor in the case in which misalignment occurs during a manufacturing process of FIG. 5.

Referring to FIGS. 9 and 10, in an image sensor according to one or more embodiments, shield conductive patterns may be selectively provided in any one of adjacent structures to reduce performance degradation caused by misalignment.

When misalignment occurs while shield conductive patterns are included in all adjacent structures, shield conductive patterns included in each of the structures may be misaligned and bonded, similarly to the first bonding pads 610 and the second bonding pads 620 of FIG. 9. Shield conductive patterns of a first structure may be disposed adjacent to second bonding pads of a second structure, and shield conductive patterns of the second structure may be disposed adjacent to first bonding pads of the first structure. In addition, parasitic capacitance may be increased between the shield conductive patterns of the first structure and the second bonding pads of the second structure, and between the first bonding pads of the first structure and the shield conductive patterns of the second structure. The shield conductive patterns included in each of the structures should be bonded to the corresponding shield conductive patterns, but may be bonded to capping portions of interlayer dielectrics due to the occurrence of misalignment. Bonding strength between the shield conductive patterns is different from bonding strength between the shield conductive pattern and the interlayer dielectric, so that bonding strength between the structures may significantly vary depending on whether misalignment occurs.

The image sensor according to one or more embodiments illustrated in FIGS. 9 and 10 may include shield conductive patterns 700, selectively provided in any one of the adjacent structures. Referring to FIGS. 9 and 10, when misalignment occurs, first bonding pads 610 of a first structure 100 may be disposed adjacent to shield conductive patterns 700 of a second structure 200, and parasitic capacitance may be increased only between the first bonding pads 610 of the first structure 100 and shield conductive patterns 700 of a second structure 200. For example, the image sensor according to one or more embodiments may reduce a decrease in conversion gain caused by misalignment.

In addition, regardless of whether misalignment occurs, the shield conductive patterns 700 of the second structure 200 may be bonded to a capping portion 413 or 423 of an interlayer dielectric 410 or 420, so that a difference in bonding strength between structures based on whether misalignment occurs may be reduced or significantly reduced. For example, the image sensor according to one or more embodiments may easily control bonding strength and device characteristic distribution a wafer.

The shield conductive patterns 700 of the image sensor according to one or more embodiments may be sequentially arranged in a row direction, as illustrated in FIG. 10. In addition, the shield conductive patterns 700 may be sequentially arranged in a column direction of FIG. 10. When the shield conductive patterns 700 are sequentially arranged in the column direction, the shield conductive patterns 700 arranged in the column direction may be connected to each other to be integrated with each other or spaced apart from each other.

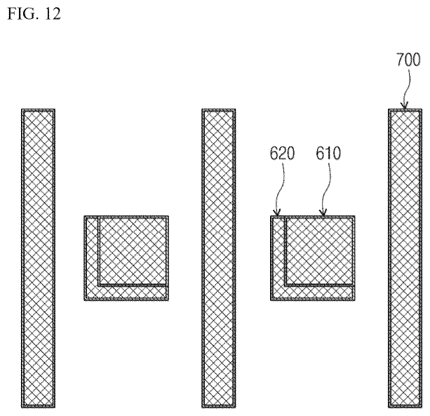

FIG. 11 is a cross-sectional view of an image sensor according to one or more embodiments, and FIG. 12 is a plan view corresponding to line I-I′ of FIG. 11. For example, FIG. 11 is a cross-sectional view of an image sensor in the case in which misalignment occurs during the manufacturing process of FIG. 8.

Referring to FIGS. 11 and 12, the image sensor according to one or more embodiments includes shield conductive patterns 700, selectively provided in any one of adjacent structures. Performance degradation caused by misalignment may be significantly reduced by increasing a width of a bonding pad of a structure in which the shield conductive patterns 700 is included, or decreasing a width of a bonding pad of a structure in which the shield conductive patterns 700 is not included.

As previously illustrated in FIGS. 9 and 10, when misalignment occurs, a first bonding pad 610 of a first structure 100 may be laterally shifted from a second bonding pad 620 of a second structure 200 and may be closer to the shield conductive pattern 700 of the second structure 200. In the image sensor illustrated in FIG. 11, a width of a first bonding pad 610 of the first structure 100 may be adjusted in consideration of a bonder ensuring a minimum-sized recognizable misalignment. Accordingly, even when misalignment occurs, the entire lower surface of the first bonding pad 610 of the first structure 100 may be in contact with the second bonding pad 620 of the second structure 200. Regardless of whether misalignment occurs, the first bonding pads 610 of the first structure 100 illustrated in FIG. 11 be maintained at a certain distance from the shield conductive patterns 700 of the second structure 200. Therefore, an increase in parasitic capacitance between the first bonding pads 610 and the shield conductive patterns 700 may be significantly reduced. For example, the image sensor according to one or more embodiments may significantly reduce a decrease in conversion gain caused misalignment.

In addition, regardless of whether misalignment occurs, the shield conductive patterns 700 of the second structure 200 may be bonded to a capping portion 413 of a lowermost first interlayer dielectric 410, and the first bonding pads 610 of the first structure 100 may be bonded to the second bonding pads 620 of the second structure 200, and contact areas between the capping portion 413 of the lowermost first interlayer dielectric 410 and the second bonding pads 620 may be substantially the same. Accordingly, a difference in bonding strength between the structures caused by misalignment may be significantly reduced. For example, the image sensor according to one or more embodiments may easily control the bonding strength and device characteristic distribution in a wafer.

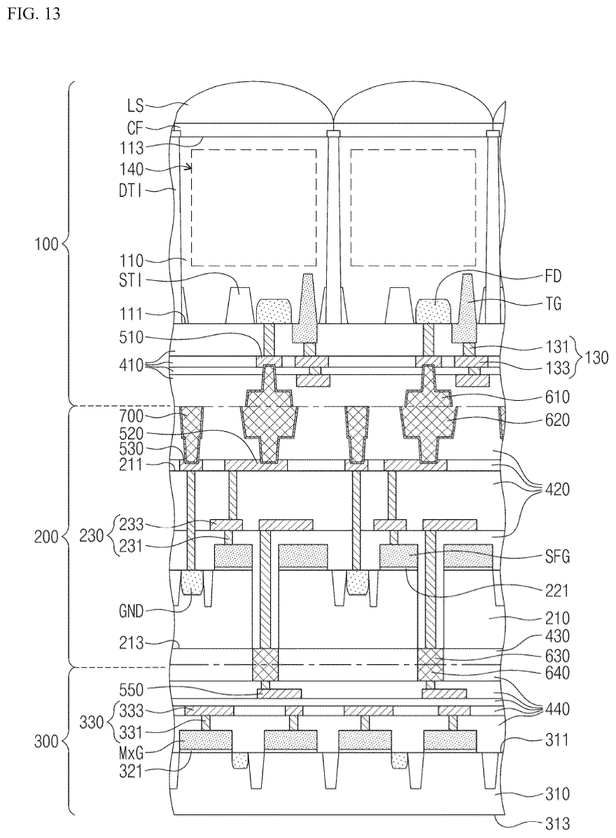

FIG. 13 is a cross-sectional view of an image sensor according to one or more embodiments.

Referring to FIG. 13, the image sensor according to one or more embodiments may include first to third structures 100, 200, and 300, and the example embodiment of FIG. 8 may be applied to the first and second structures 100 and 200. In the image sensor of FIG. 13, unlike the described-above image sensor of FIG. 3, a source follower gate SFG may be disposed on a third surface 211 of a second substrate 210 and second interlayer dielectrics 420 may be disposed on the third surface 211 of the second substrate 210 to cover the source follower gate SFG and/or other gates. Hereinafter, a structure in which the source follower gate SFG is disposed on a fourth surface 213 as illustrated in FIG. 3 may be referred to as a front-back (F-B) structure, and a structure in which the source follower gate SFG is disposed on the third surface 211 as illustrated in FIG. 13 may be referred to as a front-front (F-F) structure.

In one or more embodiments, in an image sensor having the F-F structure, a shallow device isolation pattern of the second structure 200 may be formed adjacent to the third surface 211 of the second substrate 210 to define active regions, and source/drain regions and/or a ground region GND may be formed in the active regions of the second substrate 210 adjacent to the third surface 211.

In one or more embodiments, in an image sensor having the F-B structure, a shallow device isolation pattern of the second structure 200 may be formed adjacent to the fourth surface 213 of the second substrate 210 to define active regions, and source/drain regions and/or a ground region GND may be formed in the active regions of the second substrate 210 adjacent to the fourth surface 213.

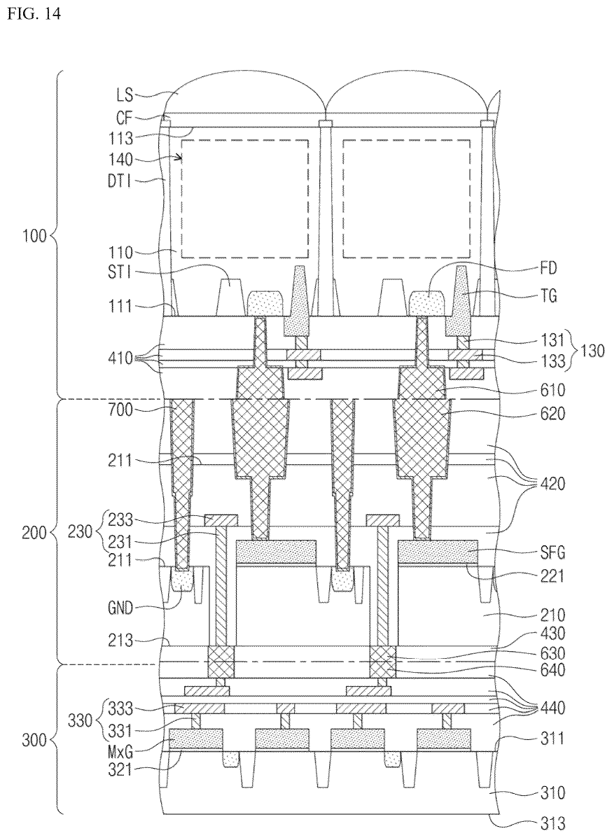

FIG. 14 is a cross-sectional view of an image sensor according to one or more embodiments.

Referring to FIG. 14, in the image sensor according to one or more embodiments, a first bonding pad 610 and a second bonding pad 620 may be directly connected to a floating diffusion region FD and a source follower gate SFG, respectively, and a shield conductive pattern 700 may be directly connected to a ground region GND. The floating diffusion region FD may correspond to a first terminal, the source follower gate SFG may correspond to a second terminal, and the ground region GND may correspond to a third terminal.

For example, first bonding pads 610 of a first structure 100 may be in direct contact with the floating diffusion regions FD of the first substrate 110 to be electrically connected thereto. The second bonding pads 620 of a second structure 200 may be in direct contact with the source follower gates SFG of the second substrate 210 to be electrically connected thereto. The shield conductive patterns 700 of the second structure 200 may be in direct contact with the ground regions GND of the second substrate 210 to be electrically connected thereto.

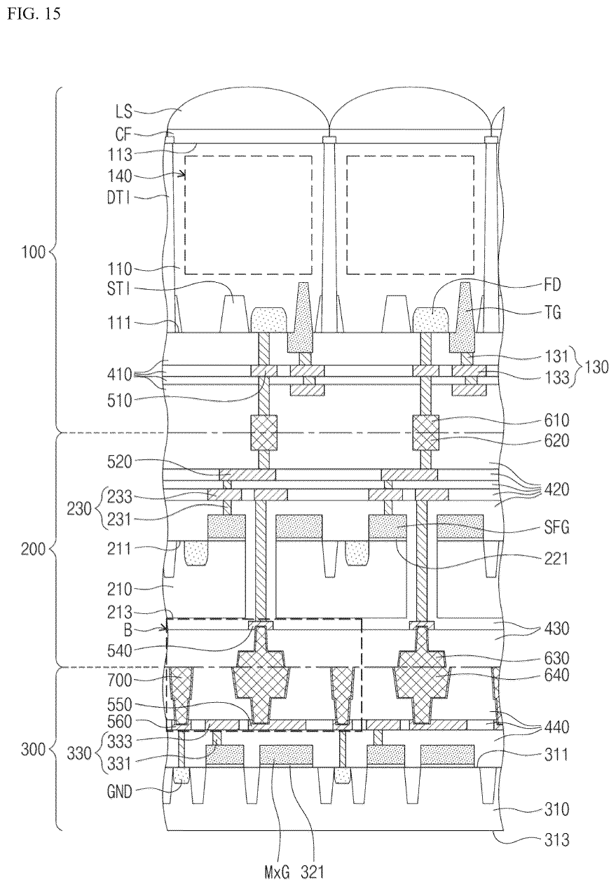

FIG. 15 is a cross-sectional view of an image sensor according to one or more embodiments.

Referring to FIG. 15, an image sensor according to one or more embodiments may include first to third structures 100, 200, and 300, and the example embodiment of FIG. 8 may be applied to the second and third structures 200 and 300. Unlike the above-described image sensor of FIG. 13, the F-F image sensor of FIG. 15 may include shield conductive patterns 700 provided in the third structure 300.

In one or more embodiments, the first and second structures 100 and 200 may not include the third terminals 530 and the shield conductive patterns 700 of FIG. 13, and the third structure 300 may further include a sixth terminals 560, shield conductive patterns 700, respectively connected to sixth terminals 560, and ground regions GND, respectively electrically connected to the shield conductive patterns 700 through the sixth terminals 560. The third bonding pad 630 may have substantially the same features as the first bonding pad 610 of FIG. 8, and the fourth bonding pad 640 may have substantially the same features as the second bonding pad 620 of FIG. 8.

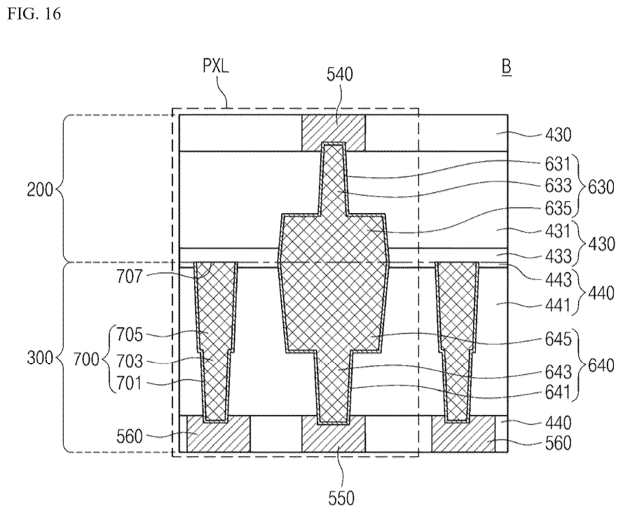

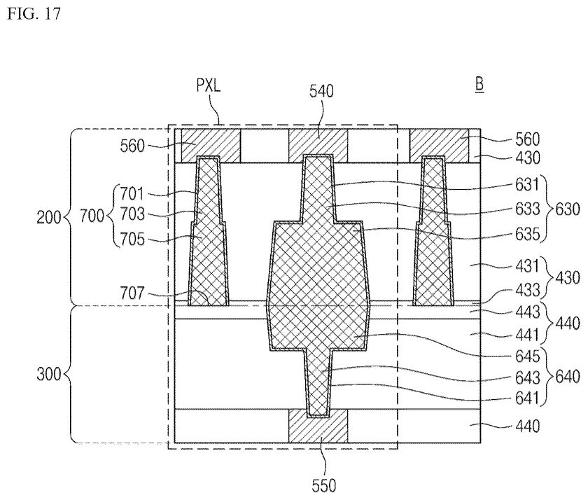

FIG. 16 is an enlarged cross-sectional view of portion ‘B’ of FIG. 15, and FIG. 17 is an enlarged cross-sectional view corresponding to portion ‘B’ of FIG. 15 and illustrating an image sensor according to one or more embodiments.

Referring to FIG. 16, the second structure 200 may include third interlayer dielectrics 430, a fourth terminal 540 provided in one of the third interlayer dielectrics 430, and a third bonding pad 630 provided in another of the third interlayer dielectrics 430. The another of the third interlayer dielectrics 430 may be a lowermost third interlayer dielectric 430. The third structure 300 may include fourth interlayer dielectrics 440, fifth and sixth terminals 550 and 560 provided in one of the fourth interlayer dielectrics 440, a fourth bonding pad 640 provided in another of the fourth interlayer dielectrics 440, and a shield conductive pattern 700 provided in the other of the fourth interlayer dielectrics 440. The another of the fourth interlayer dielectrics 440 may be an uppermost fourth interlayer dielectric 440.

In one or more embodiments, the lowermost third interlayer dielectric 430 may include a body portion 431 and a capping portion 433 provided on a lower surface of the body portion 431. The capping portion 433 may be formed of the same material as, or a material different from, a material of the body portion 431. The uppermost fourth interlayer dielectric 440 may include a body portion 441 and a capping portion 443 provided on an upper surface of the body portion 441. The capping portion 443 may be formed of the same material as, or a material different from, a material of the body portion 441. In one or more embodiments, the capping portion 433 of the lowermost third interlayer dielectric 430 may be in contact with the capping portion 443 of the uppermost fourth interlayer dielectric 440. The body portions 431 and 441 may be formed of the above-mentioned first insulating material, and the capping portions 433 and 443 may be formed of the above-mentioned second insulating material.

In one or more embodiments, the third bonding pad 630 may include a third pad via portion 633 provided adjacent to a fourth terminal 540 within the lowermost third interlayer dielectric 430, a third pad portion 635 provided below the third pad via portion 633, and a third conductive liner 631 covering (or contacting) external surfaces of the third pad via portion 633 and the third pad portion 635 and contacting the fourth terminal 540. The third pad via portion 633 and the third pad portion 635 may be vertically aligned and may be in contact with each other without an interface therebetween. The third conductive liner 631 may serve as a seed layer and/or a diffusion barrier layer.

The fourth bonding pad 640 may include a fourth pad via portion 643 provided adjacent to the fifth terminal 550 within the uppermost fourth interlayer dielectric 440, a fourth pad portion 645 provided on the fourth pad via portion 643, and a fourth conductive liner 641 covering (or contacting) external surfaces of the fourth pad via portion 643 and the fourth pad portion 645 and contacting the fifth terminal 550. The fourth pad via portion 643 and the fourth pad portion 645 may be vertically aligned and may be in contact with each other without an interface therebetween. The fourth conductive liner 631 may serve as a seed layer and/or a diffusion barrier layer.

In one or more embodiments, the shield conductive pattern 700 may include a pattern via portion 703 provided adjacent to the sixth terminal 560 within the uppermost fourth interlayer dielectric 440, a pattern portion 705 provided on the pattern via portion 703, and a pattern conductive liner 701 covering external surfaces of the pattern via portion 703 and the pattern portion 705 and contacting the sixth terminal 530. The pattern via portion 703 and the pattern portion 705 may be vertically aligned to be in contact with each other without an interface therebetween. The pattern conductive liner 701 may not be provided on an upper surface of the pattern portion 705. The pattern via portion 703 may have a smaller width than the pattern portion 705. In one or more embodiments, the pattern via portion 703 may have a width increasing in a direction away from the sixth terminal 560, and the pattern portion 705 may have a width increasing in a direction away from the pattern via portion 703. A maximum width of the pattern via portion 703 may be smaller than a minimum width of the pattern portion 705.

In the present specification, the sixth terminal 560 may be referred to as a lower shield terminal.

In one or more embodiments, the third bonding pad 630 may have a smaller thickness (or height) than the fourth bonding pad 640. For example, the pad portion 635 of the third bonding pad 630 may have a smaller thickness than the pad portion 645 of the fourth bonding pad 640. Also, the pad via portion 633 of the third bonding pad 630 may have a smaller thickness than the pad via portion 643 of the fourth bonding pad 640. Such a relative thickness difference may be selectively applied to at least one of the thickness of the pad portion and the thickness of the pad via portion.

In one or more embodiments, the third bonding pad 630 may have a smaller width than the fourth bonding pad 640. For example, the pad portion 635 of the third bonding pad 630 may have a smaller width than the pad portion 645 of the fourth bonding pad 640. Also, the pad via portion 633 of the third bonding pad 630 may have a smaller width than the pad via portion 643 of the fourth bonding pad 640. Such a relative width difference may be selectively applied to at least one of the width of the pad portion and the width of the pad via portion.

Referring to FIG. 17, the second structure 200 may include third interlayer dielectrics 430, a fourth terminal and a sixth terminal 540 and 560 provided in one of the third interlayer dielectrics 430, a third bonding pad 630 provided in another of the third interlayer dielectrics 430, and a shield conductive pattern 700 provided in the another of the third interlayer dielectrics 430. The another of the third interlayer dielectrics 430 may be a lowermost third interlayer dielectric 430. The fourth structure 400 may include fourth interlayer dielectrics 440, a fifth terminal 550 provided in one of the fourth interlayer dielectrics 440, and a fourth bonding pad 640 provided in another of the fourth interlayer dielectrics 440. The another of the fourth interlayer dielectrics 440 may be an uppermost fourth interlayer dielectric 440. For example, while the sixth terminal 560 and the shield conductive pattern 700 are provided in the third structure 300 in the above-described embodiment of FIG. 16, the sixth terminal 560 and the shield conductive pattern 700 may be provided in the second structure 200 in the embodiment of FIG. 17. The shield conductive pattern 700 may be provided in one of the third and fourth interlayer dielectrics 430 and 440, and may have a pattern surface 707 directed toward the another of the third and fourth interlayer dielectrics 430 and 440. The entire pattern surface 705 of the shield conductive pattern 700 may be in contact with the another of the third and fourth interlayer dielectrics 430 and 440.

In one or more embodiments, the shield conductive pattern 700 may include a pattern via portion 703 provided adjacent to the sixth terminal 560 within the lowermost third interlayer dielectric 430, a pattern portion 705 provided below the pattern via portion 703, and a pattern conductive liner 701 covering external surfaces of the pattern via portion 703 and the pattern portion 705 and contacting the sixth terminal 560. The pattern conductive liner 701 may not be provided on a lower surface of the pattern portion 705.

In one or more embodiments, the fourth bonding pad 640 may have a smaller thickness (or height) than the third bonding pad 630. For example, the pad portion 645 of the fourth bonding pad 640 may have a smaller thickness than the pad portion 635 of the third bonding pad 630. Also, the pad via portion 643 of the fourth bonding pad 640 may have a smaller thickness than the pad via portion 633 of the third bonding pad 630. Such a relative thickness difference may be selectively applied to at least one of the thickness of the pad portion and the thickness of the pad via portion.

In one or more embodiments, the fourth bonding pad 640 may have a smaller width than the third bonding pad 630. For example, the pad portion 645 of the fourth bonding pad 640 may have a smaller width than the pad portion 635 of the third bonding pad 630. Also, the pad via portion 643 of the fourth bonding pad 640 may have a smaller width than the pad via portion 633 of the third bonding pad 630. Such a relative width difference may be selectively applied to at least one of the width of the pad portion and the width of the pad via portion.

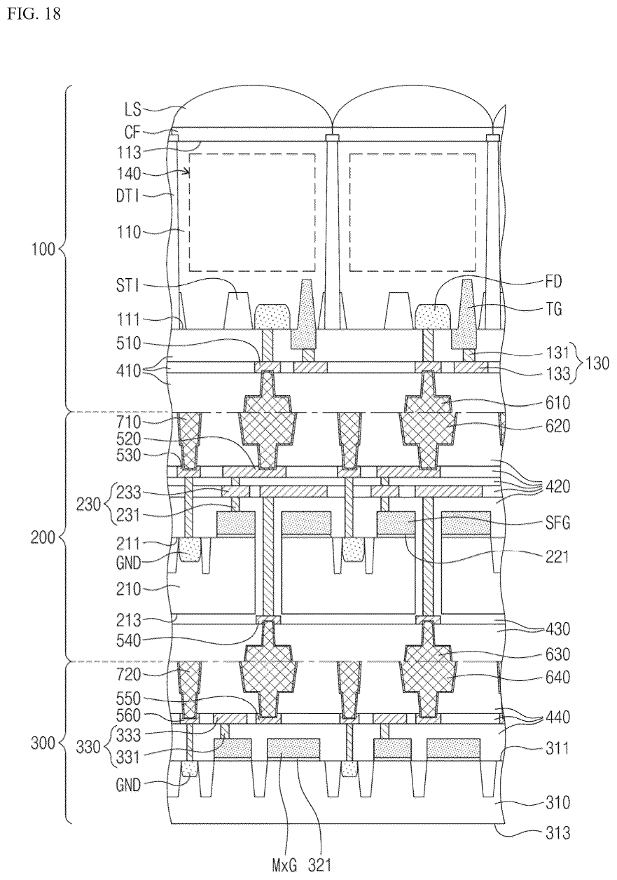

FIGS. 18 to 21 are cross-sectional views of image sensors according to one or more embodiments.

Referring to FIGS. 18 to 21, an image sensor having an F-F structure according to one or more embodiments may include a shield conductive pattern 710 between first and second substrates 110 and 210 and a shield conductive pattern 720 between second and third substrates 210 and 310. In the present specification, the shield conductive pattern 710 between the first and second substrates 110 and 210 may be referred to as a first shield conductive pattern or an upper shield conductive pattern, and the shield conductive pattern 720 disposed between the second and third substrates 210 and 310 may be referred to as an additional shield conductive pattern, a second shield conductive pattern, or a lower shield conductive pattern.

Referring to FIG. 18, third terminals 530 and upper shield conductive patterns 710 may be disposed in second interlayer dielectrics 420, and the sixth terminals 560 and lower shield conductive patterns 720 may be disposed in fourth interlayer dielectrics 440. Second bonding pads 620 in a second interlayer dielectric 420 may have a larger width and/or a larger thickness than a first bonding pads 610 in a first interlayer dielectric 410, and fourth bonding pads 640 in the fourth interlayer dielectric 440 may have a larger width and/or a larger thickness than third bonding pads 630 in third interlayer dielectric 430.

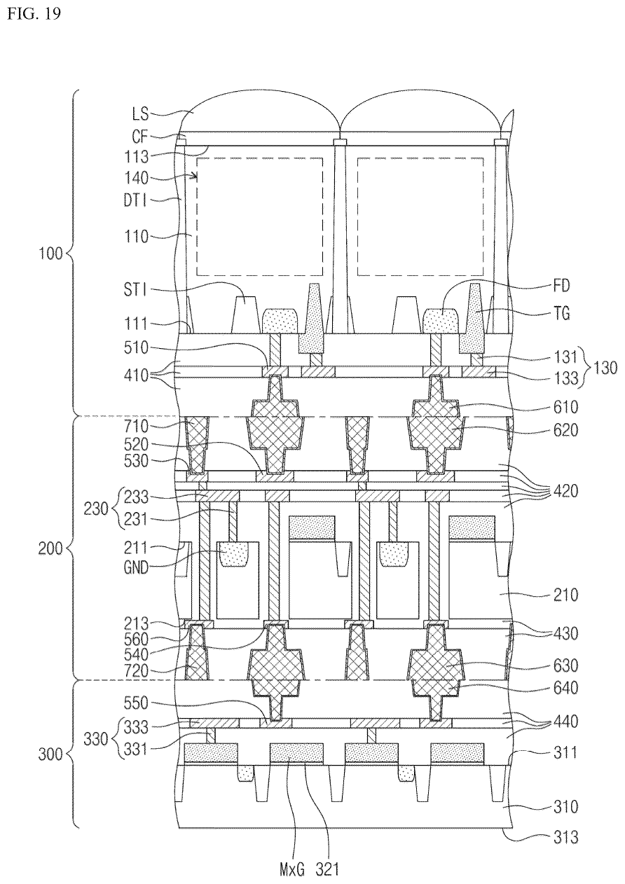

Referring to FIG. 19, third terminals 530 and upper shield conductive patterns 710 may be disposed in the second interlayer dielectrics 420, and sixth terminals 560 and the lower shield conductive patterns 720 may be disposed in the third interlayer dielectrics 430. Second bonding pads 620 in second interlayer dielectric 420 may have a larger width and/or a larger thickness than first bonding pads 610 in a first interlayer dielectric 410, and third bonding pads 630 in a third interlayer dielectric 430 may have a larger width and/or a larger thickness than fourth bonding pads 640 in a fourth interlayer dielectric 440.

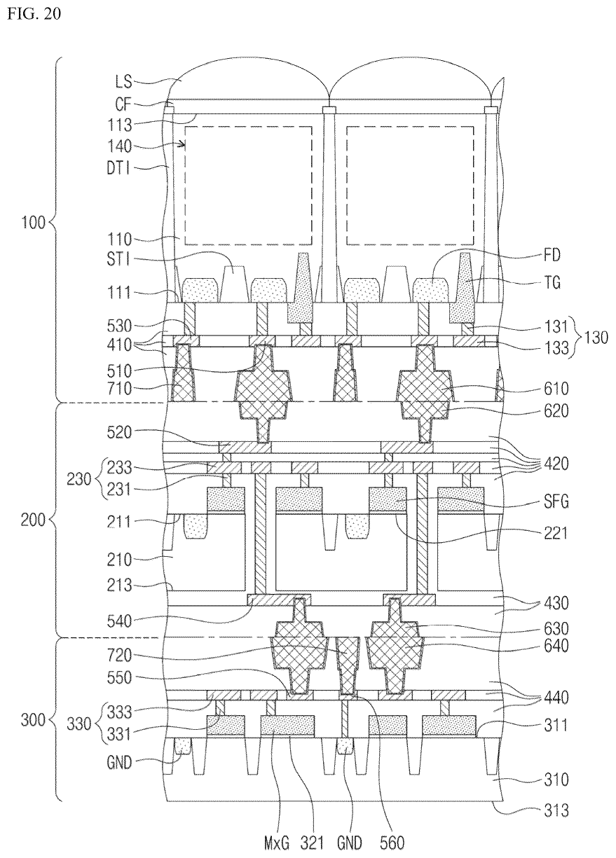

Referring to FIG. 20, a third terminals 530 and upper shield conductive patterns 710 may be disposed in the first interlayer dielectrics 410, and sixth terminals 560 and lower shield conductive patterns 720 may be disposed in fourth interlayer dielectrics 440. First bonding pads 610 in first interlayer dielectric 410 may have a larger width and/or a larger thickness than second bonding pads 620 in second interlayer dielectric 420, and fourth bonding pads 640 in a fourth interlayer dielectric 440 may have a larger width and/or a larger thickness than third bonding pads 630 in a third interlayer dielectric 430.

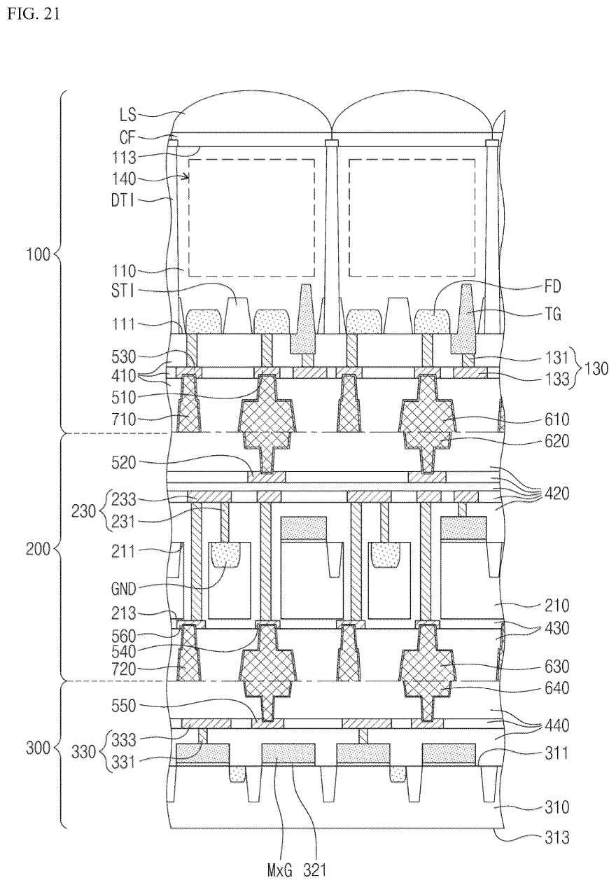

Referring to FIG. 21, third terminals 530 and upper shield conductive patterns 710 may be disposed in first interlayer dielectrics 410, and sixth terminals 560 and the lower shield conductive patterns 720 may be disposed in third interlayer dielectrics 430. First bonding pads 610 in a first interlayer dielectric 410 may have a larger width and/or a larger thickness than second bonding pads 620 in a second interlayer dielectric 420, and third bonding pads 630 in a third interlayer dielectric 430 may have a larger width and/or a larger thickness than fourth bonding pads 640 in a fourth interlayer dielectric 440.

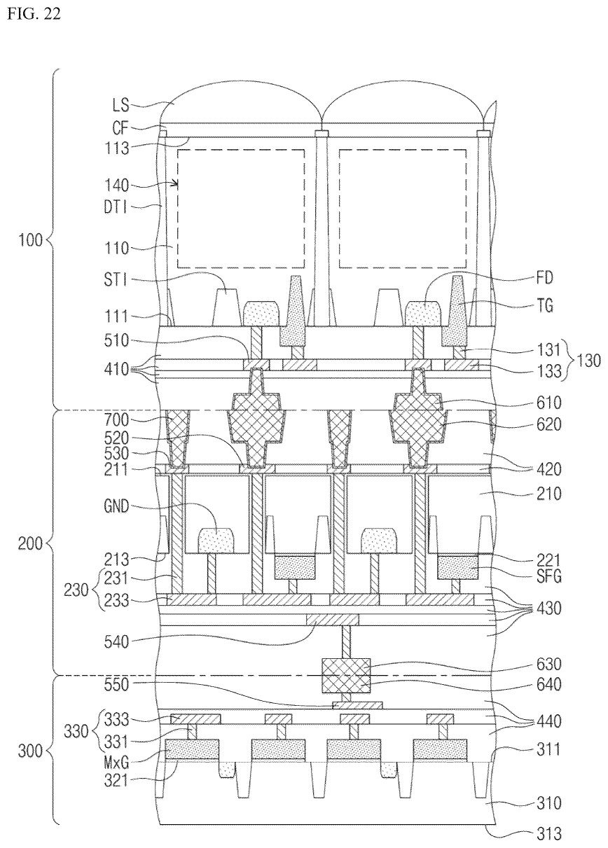

FIG. 22 is a cross-sectional view of an image sensor according to one or more embodiments.

Referring to FIG. 22, an image sensor having an F-B structure according to one or more embodiments may include first to third structures 100, 200, and 300, and the example embodiment of FIG. 8 may be applied to the first and second structures 100 and 200. Unlike the above-described image sensor having an F-F structure of FIG. 13, the image sensor having the F-B structure of FIG. 22 may include a source follower gate SFG disposed on a fourth surface 213 of a second substrate 210 and a third interlayer dielectric 430 disposed on the fourth surface 213 of the second substrate 210 to cover the source follower gate SFG and/or other gates.

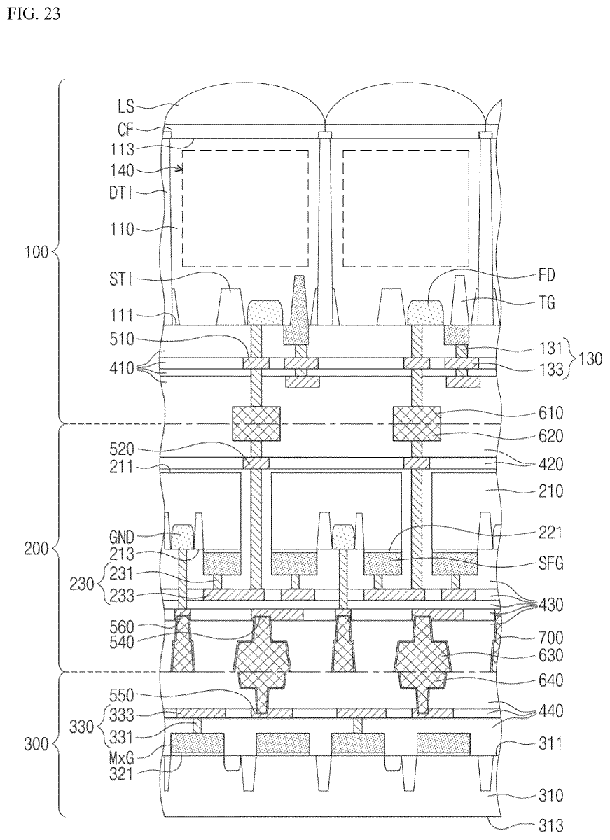

FIG. 23 is a cross-sectional view of an image sensor according to one or more embodiments.

Referring to FIG. 23, an image sensor having an F-B structure according to one or more embodiments may include first to third structures 100, 200, and 300, and some features and the relative width difference between the bonding pads of FIG. 17 may be applied to the second and third structures 200 and 300.

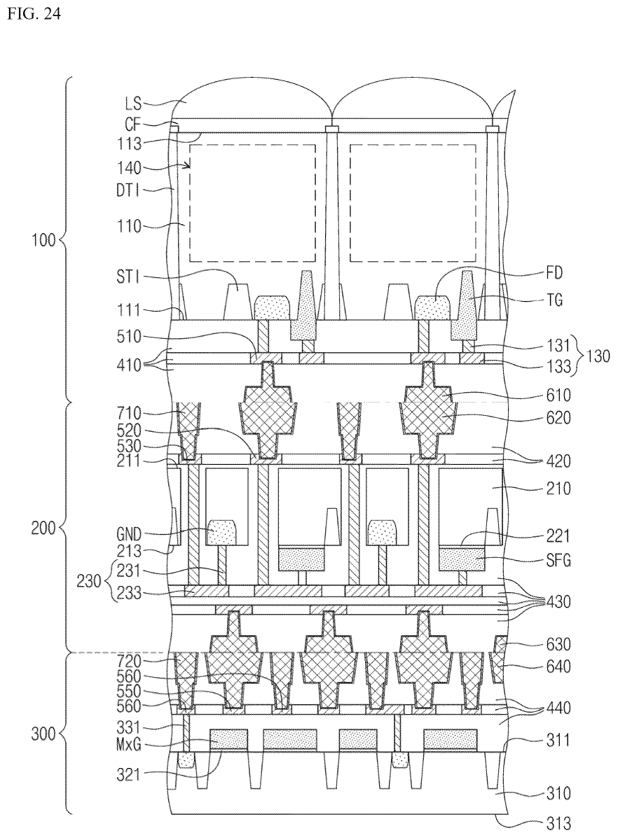

FIGS. 24 to 27 are cross-sectional views of image sensors according to one or more embodiments.

Referring to FIGS. 24 to 27, an image sensor having an F-B structure according to one or more embodiments may include upper shield conductive patterns 710 between a first substrate 110 and a second substrate 210 and lower shield conductive patterns 720 between the second substrate 210 and a third substrate 310.

Referring to FIG. 24, third terminals 530 and the upper shield conductive patterns 710 may be disposed in second interlayer dielectrics 420, and sixth terminals 560 and the lower shield conductive patterns 720 may be disposed in fourth interlayer dielectrics 440. Second bonding pads 620 in the second interlayer dielectric 420 may have a larger width and/or a larger thickness than first bonding pads 610 in a first interlayer dielectric 410, and fourth bonding pads 640 in a fourth interlayer dielectric 440 may have a larger width and/or a larger thickness than third bonding pads 630 in a third interlayer dielectric 430.

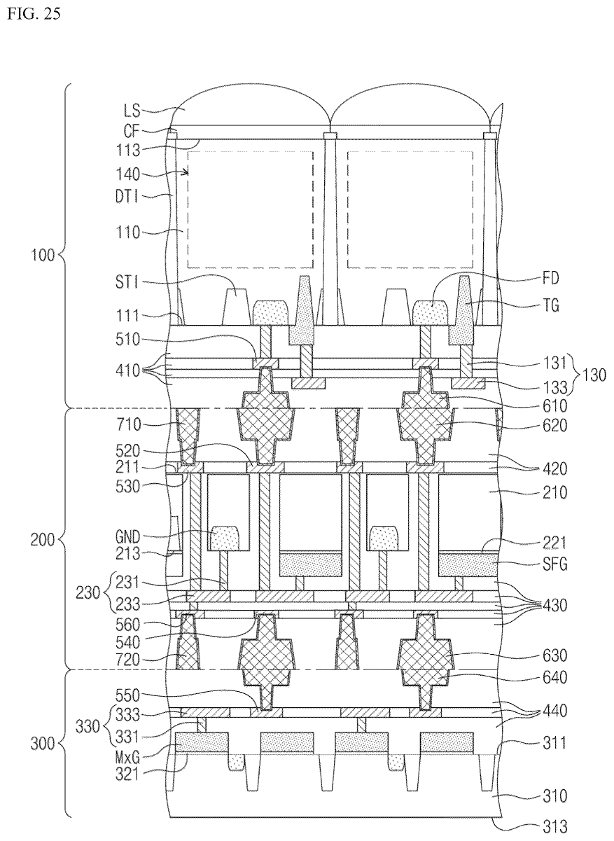

Referring to FIG. 25, third terminals 530 and upper shield conductive patterns 710 may be disposed in second interlayer dielectrics 420, and sixth terminals 560 and lower shield conductive patterns 720 may be disposed in third interlayer dielectrics 430. Second bonding pads 620 in the second interlayer dielectric 420 may have a larger width and/or a larger thickness than first bonding pads 610 in a first interlayer dielectric 410, and third bonding pads 630 in a third interlayer dielectric 430 may have a larger width and/or a larger thickness than fourth bonding pads 640 in a fourth interlayer dielectric 440.

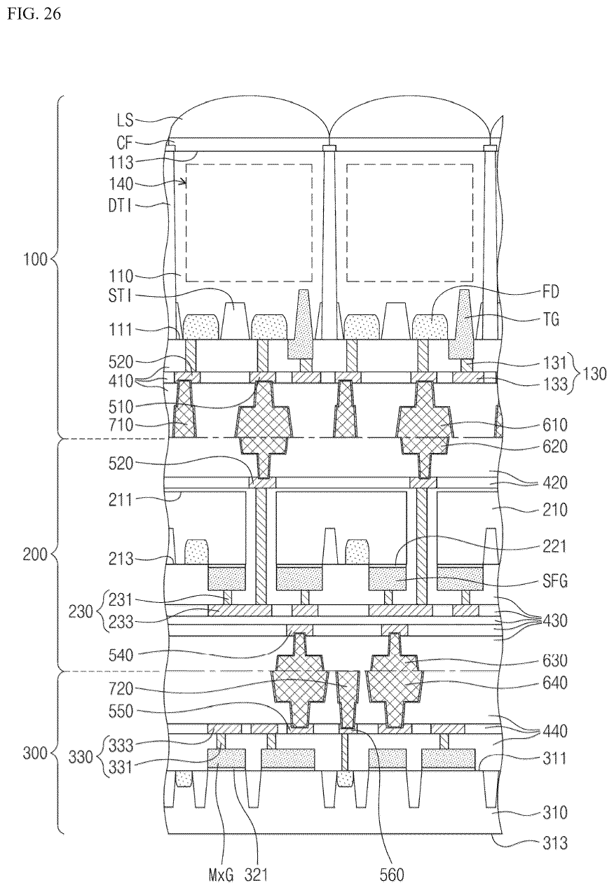

Referring to FIG. 26, third terminals 530 and upper shield challenge patterns 710 may be disposed in first interlayer dielectrics 410, and sixth terminals 560 and lower shield conductive patterns 720 may be disposed in fourth interlayer dielectrics 440. First bonding pads 610 in the first interlayer dielectric 410 may have a larger width and/or thickness than second bonding pads 620 in a second interlayer dielectric 420, and fourth bonding pads 640 in a fourth interlayer dielectric 440 may have a larger width and/or thickness than third bonding pads 630 in a third interlayer dielectric 430.

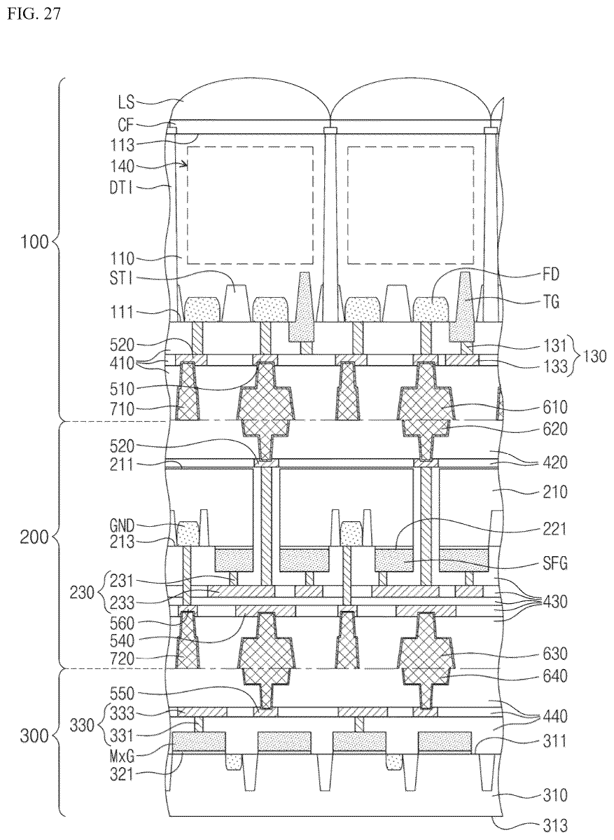

Referring to FIG. 27, third terminals 530 and upper shield conductive patterns 710 may be disposed in first interlayer dielectrics 410, and sixth terminals 560 and lower shield conductive patterns 720 may be disposed in third interlayer dielectrics 430. First bonding pads 610 in the first interlayer dielectric 410 may have a larger width and/or thickness than second bonding pads 620 in a second interlayer dielectric 420, and third bonding pads 630 in a third interlayer dielectric 430 may have a larger width and/or thickness than fourth bonding pads 640 in a fourth interlayer dielectric 440.

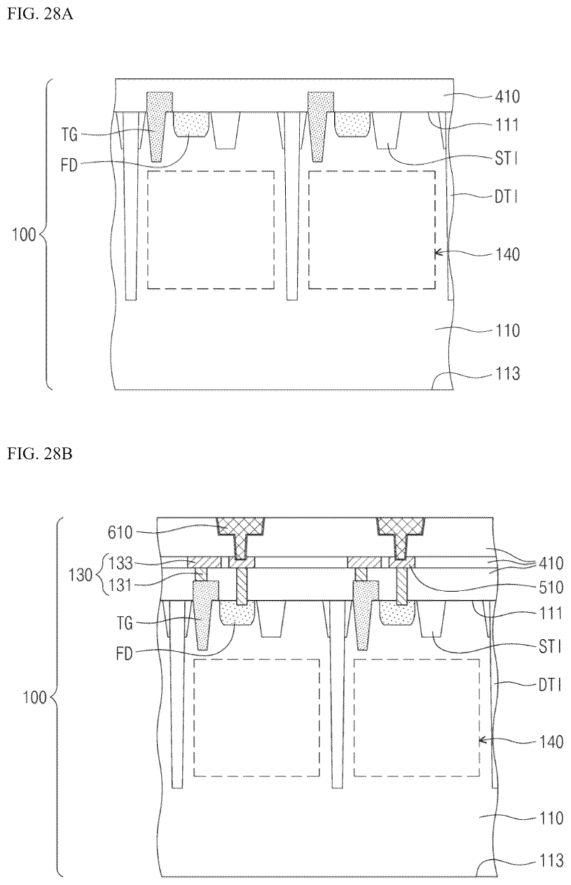

FIGS. 28A to 34 are cross-sectional views illustrating a method of manufacturing an image sensor according to one or more embodiments. An image sensor having an F-F structure may be manufactured through FIGS. 28A to 34.

Referring to FIGS. 28A and 28B, a photoelectric conversion structure 100 of an image sensor may be formed. For example, photoelectric conversion regions 140 may be formed in a first substrate 110, and a deep trench isolation pattern DTI and a shallow trench isolation pattern STI may be formed in the first substrate 110. According to one or more embodiments, a lower surface of the deep trench isolation pattern DTI may be spaced from a second surface 113 of the first substrate 110. The photoelectric conversion regions 140 may be formed using an ion implantation process, and may be formed before or after the formation of the deep and shallow trench isolation patterns DTI and STI. Transfer gates TG may be formed on a first surface 111 of the first substrate 110 with a gate insulating layer interposed therebetween, and floating diffusion regions FD may be formed in active regions of the first substrate 110. First interlayer dielectrics 410 may be formed to cover the first surface 111 of the first substrate 110 and transfer gate TG, and contact plugs 131, contact interconnections 133, and first terminals 510 may be formed in the first interlayer dielectrics 410. First bonding pads 610 may be formed in an uppermost interlayer dielectric among the first interlayer dielectrics 410. First bonding pads 610 may be formed on first terminals 510.

Referring to FIGS. 29A and 29B, an intermediate structure 200 of an image sensor may be formed. A shallow trench isolation pattern STI may be formed to fill a shallow trench recessed from a third surface 211 of a second substrate 210. A source follower gate SFG may be formed on the third surface 211 of the second substrate 210 with a gate insulating layer 221 interposed therebetween. Ground regions GND may be formed in corresponding active regions of the second substrate 210 defined by the shallow trench isolation pattern STI. Second interlayer dielectrics 420 may be formed on the third surface 211 of the second substrate 210 and on the source follower gate SFG, and contact plugs 231, contact interconnections 233, second terminals 520, and third terminals 530 may be formed in the second interlayer dielectrics 420. Second bonding pads 620 and upper shield conductive patterns 710 may be formed in an uppermost interlayer dielectric among the second interlayer dielectrics 420. The second bonding pad 620 may be formed on the second terminal 520, and the upper shield conductive pattern 710 may be formed on the third terminal 530.

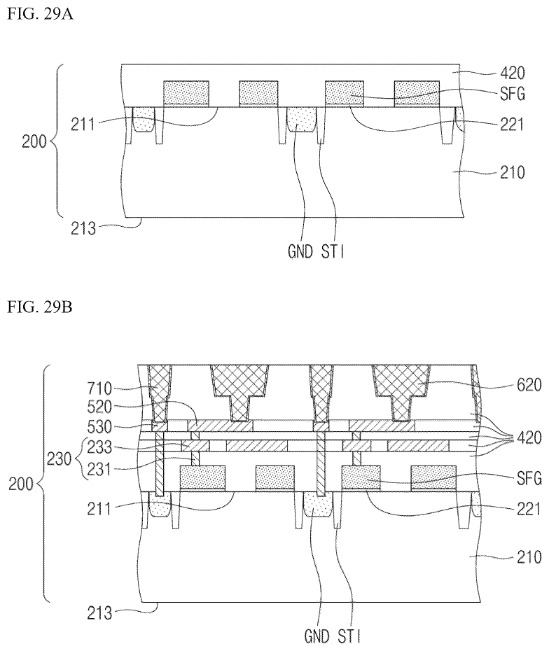

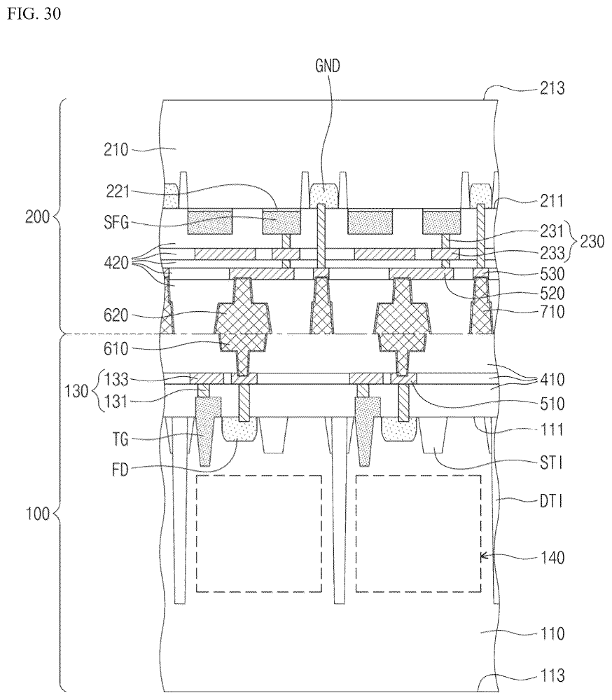

Referring to FIG. 30, the photoelectric conversion structure 100 and the intermediate structure 200 may be bonded to each other. The first and second bonding pads 610 and 620 may be bonded to each other by a copper-copper bonding technique, and the first and second interlayer dielectrics 410 and 420 may be covalently bonded.

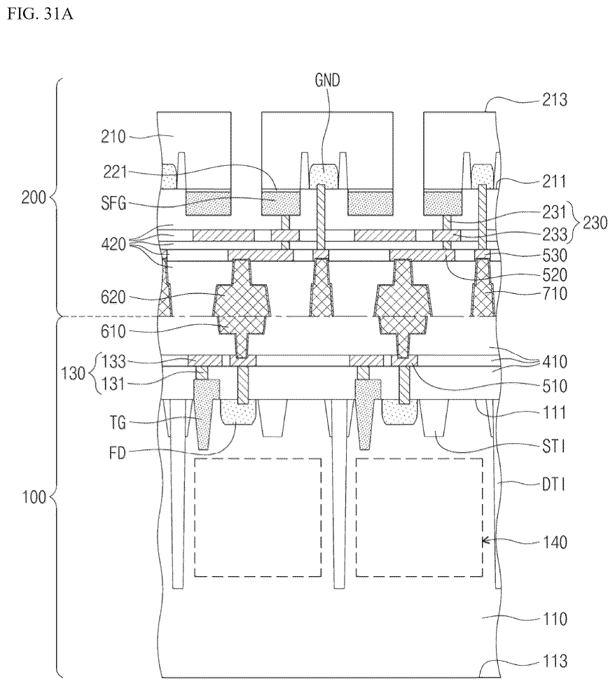

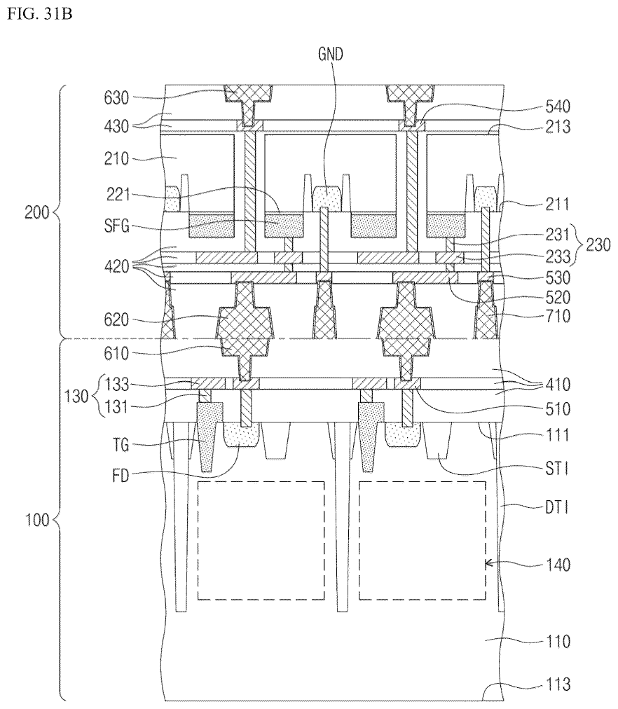

Referring to FIGS. 31A and 31B, the intermediate structure 200 may be processed. In one or more embodiments, a fourth surface 213 of the intermediate structure 200 may be etched. A third interlayer dielectric 430 may be formed on the fourth surface 213 of the second substrate 210. A hole may be formed to penetrate through the second substrate 210 and the third and fourth surfaces 211 and 213, and a contact plug 231 may be formed in the hole. The remaining third interlayer dielectrics 430 may be formed on the fourth surface 213 of the second substrate 210, and a fourth terminal 540 may be formed in a corresponding one of the third interlayer dielectrics 430. The fourth terminal 540 may be formed on the contact plug 231 penetrating through the fourth surface 213 of the second substrate 210. A third bonding pad 630 may be formed in an uppermost interlayer dielectric, among the third interlayer dielectrics 430, and may be formed on the fourth terminal 540.

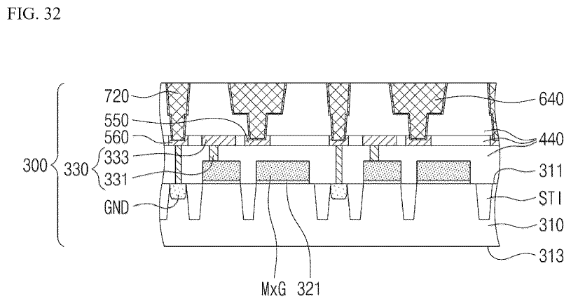

Referring to FIG. 32, a peripheral circuit structure 300 of the image sensor may be formed. A shallow trench isolation pattern STI may be formed to fill a shallow trench recessed from a fifth surface 311 of a third substrate 310. A peripheral circuit gate MxG may be formed on the fifth surface 311 of the third substrate 310 with a gate insulating layer 321 interposed therebetween. A ground region GND may be formed in a corresponding active region, among active regions of the third substrate 310 defined by the shallow trench isolation pattern STI. Fourth interlayer dielectrics 440 may be formed on a fifth surface 311 of a third substrate 310 and the peripheral circuit gate MxG, and contact plugs 331, contact interconnections 333, fifth terminals 550, and sixth terminals 560 may be formed in the fourth interlayer dielectrics 440. Fourth bonding pads 640 and lower shield conductive patterns 720 may be formed in an uppermost interlayer dielectric among the fourth interlayer dielectrics 440. The fourth bonding pad 640 may be formed on the fifth terminal 550, and the lower shield conductive pattern 720 may be formed on the sixth terminal 560.

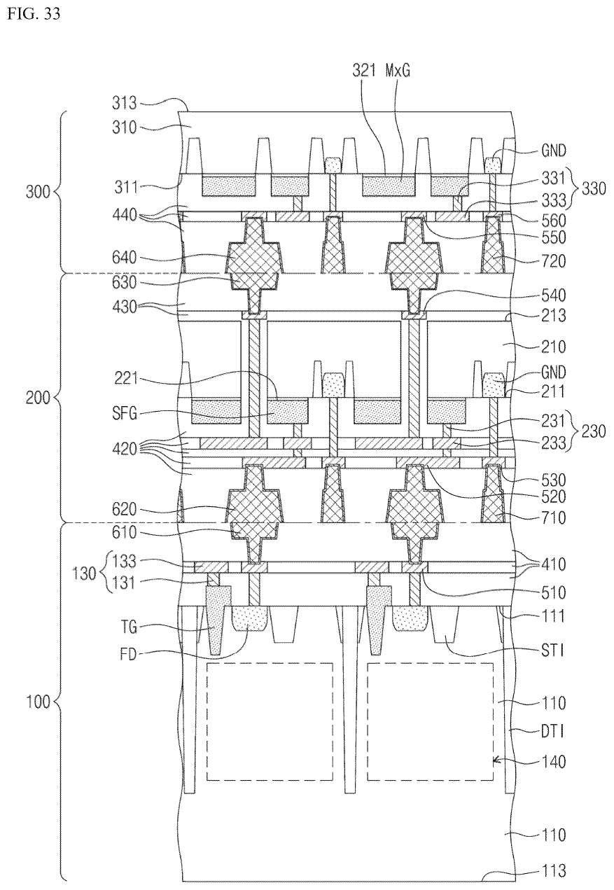

Referring to FIG. 33, the intermediate structure 200 and the peripheral circuit structure 300 may be bonded to each other. The third and fourth bonding pads 630 and 640 may be bonded to each other by a copper-copper bonding technique, and the third and fourth interlayer dielectrics 430 and 440 may be covalently bonded.

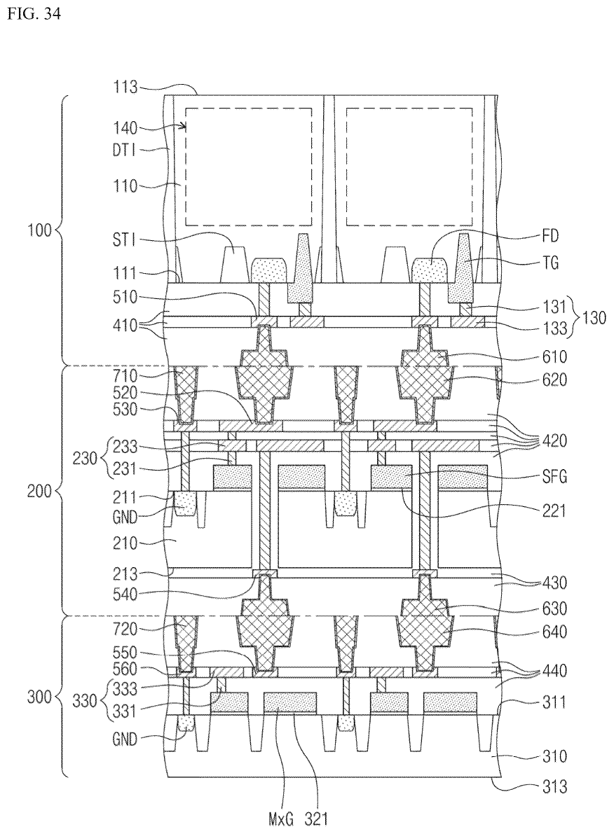

Referring to FIG. 34, the photoelectric conversion structure 100 may be processed. In one or more embodiments, a second surface 113 of the first substrate 110 of the photoelectric conversion structure 100 may be polished until the deep trench isolation pattern DTI is exposed.

Returning to FIG. 18, a substrate insulating layer, may be formed on the second surface 113 of the first substrate 110. Color filters CF may be formed on the substrate insulating layer, and microlenses LS may be formed on the color filters CF.

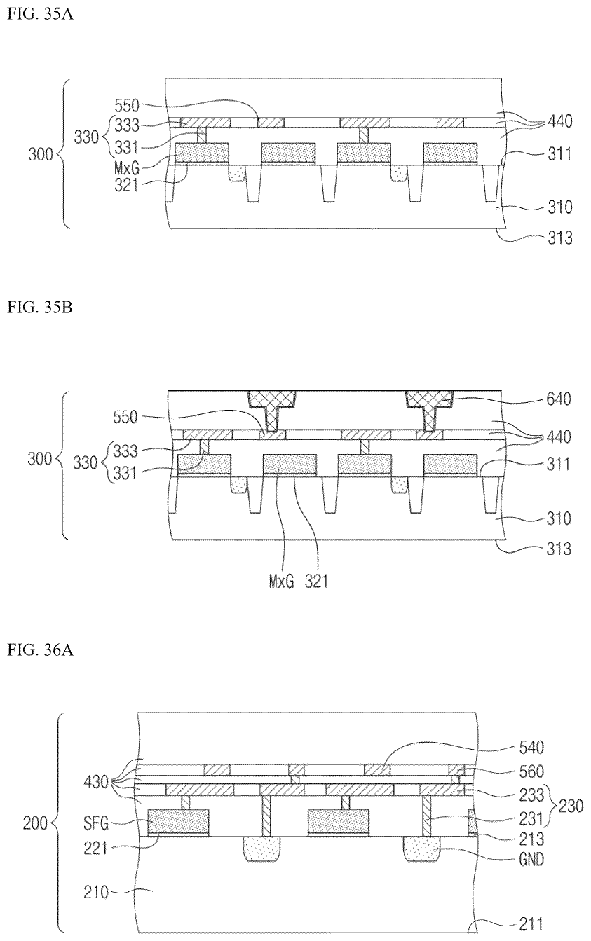

FIGS. 35A to 41 are cross-sectional views illustrating a method of manufacturing an image sensor according to one or more embodiments. An image sensor having an F-B structure may be manufactured through FIGS. 35A to 41.

Referring to FIGS. 35A and 35B, a peripheral circuit structure 300 of the image sensor may be formed. A shallow trench isolation pattern may be formed to fill a shallow trench recessed from a fifth surface 311 of a peripheral circuit substrate 310. A peripheral circuit gate MxG may be formed on the fifth surface 311 of the peripheral circuit substrate 310 with a gate insulating layer 321 interposed therebetween. Peripheral circuit interlayer dielectrics 440 may be formed on the fifth surface 311 of the peripheral circuit substrate 310 and the peripheral circuit gate MxG, and contact plugs 331, contact interconnections 333, and fifth terminals 550 may be formed in the peripheral circuit interlayer dielectrics 440. A peripheral circuit bonding pad 640 may be formed in an uppermost peripheral interlayer dielectric, among the peripheral circuit interlayer dielectrics 440, and may be formed on the peripheral circuit terminal 550.

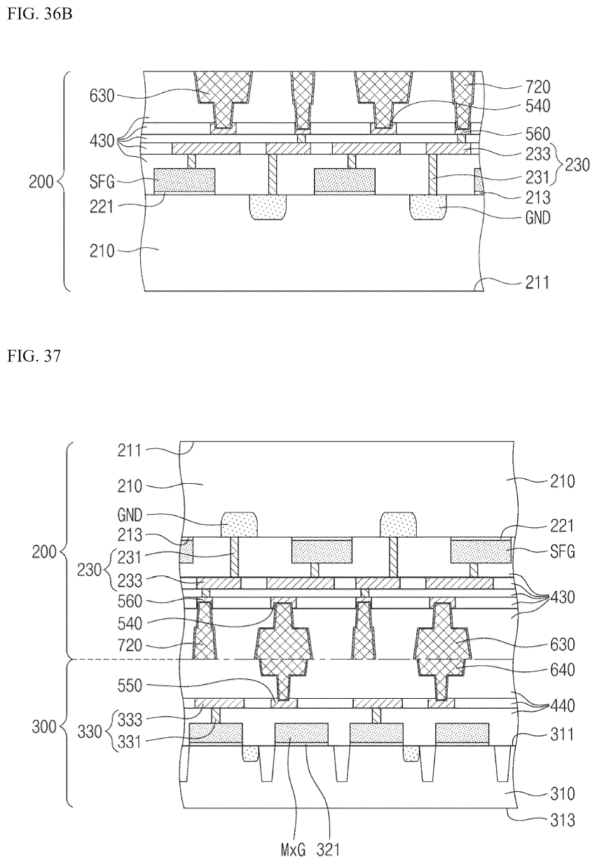

Referring to FIGS. 36A and 36B, an intermediate structure 200 of the image sensor may be formed. A shallow trench isolation pattern STI may be formed to fill a shallow trench recessed from a fourth surface 213 of an intermediate substrate 210. A source follower gate SFG may be formed on the fourth surface 213 of the intermediate substrate 210 with a gate insulating layer 221 interposed therebetween. A ground region GND may be formed in a corresponding active region, among active region of the intermediate substrate 210 defined by the shallow trench isolation pattern STI. First intermediate interlayer dielectrics 430 may be formed on the fourth surface 213 of the intermediate substrate 210 and the source follower gate SFG. Contact plugs 231, contact interconnections 233, first intermediate terminals 540, and lower shield terminals 560 may be formed in the first intermediate interlayer dielectrics 430. First intermediate bonding pads 630 and lower shield conductive patterns 720 may be formed in an uppermost interlayer dielectric among the first intermediate interlayer dielectrics 430. The first intermediate bonding pad 630 may be formed on the first intermediate terminal 540, and the lower shield conductive pattern 720 may be formed on the lower shield terminal 560.

Referring to FIG. 37, the intermediate structure 200 and the peripheral circuit structure 300 may be bonded to each other. The first intermediate and peripheral circuit bonding pads 630 and 640 may be bonded to each other by a copper-copper bonding technique, and the first intermediate and peripheral circuit interlayer dielectrics 430 and 440 may be covalently bonded.

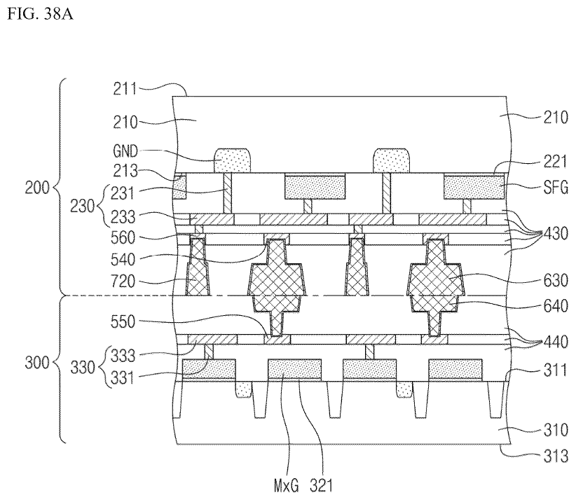

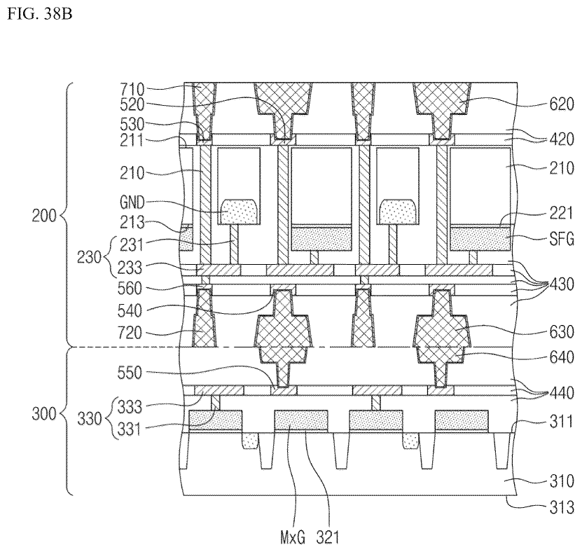

Referring to FIGS. 38A and 38B, the intermediate structure 200 may be processed. In one or more embodiments, the third surface 211 of the intermediate structure 200 may be etched. A second intermediate interlayer dielectric 420 may be formed on the third surface 211 of the intermediate substrate 210. A hole may be formed to penetrate through the intermediate substrate 210 and the third and fourth surfaces 211 and 213, and a contact plug 231 may be formed in the hole. The remaining second intermediate interlayer dielectrics 420 may be formed on the third surface 211 of the intermediate substrate 210, and second intermediate and upper shield terminals 520 and 530 may be formed in a corresponding one of the second intermediate interlayer dielectrics 420. Second intermediate bonding pads 620 and upper shield conductive patterns 710 may be formed in an uppermost intermediate interlayer dielectric among the second intermediate interlayer dielectrics 420. The second intermediate bonding pad 620 may be formed on the second intermediate terminal 520, and the upper shield conductive pattern 710 may be formed on the upper shield terminal 530.

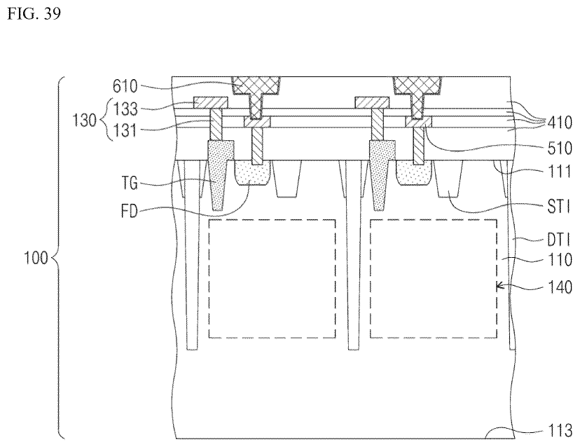

Referring to FIG. 39, a photoelectric conversion structure 100 of the image sensor may be formed. Photoelectric conversion regions 140 may be formed in the photoelectric conversion substrate 110, and a deep trench isolation pattern DTI and a shallow trench isolation pattern STI may be formed in the photoelectric conversion substrate 110. Transfer gates TG may be formed on the first surface 111 of the photoelectric conversion substrate 110 with a gate insulating layer interposed therebetween, and floating diffusion regions FD may be formed in a corresponding active region, among active regions of the photoelectric conversion substrate 110. Photoelectric conversion interlayer dielectrics 410 may be formed on the first surface 111 of the photoelectric conversion substrate 110 and the transfer gate TG, and contact plugs 131, contact interconnections 133, and photoelectric conversion terminals 510 may be formed in the photoelectric conversion interlayer dielectrics 410. Photoelectric conversion bonding pads 610 may be formed in an uppermost photoelectric conversion interlayer dielectric, among the photoelectric conversion interlayer dielectrics 410. The photoelectric conversion bonding pad 610 may be formed on the photoelectric conversion terminal 510.

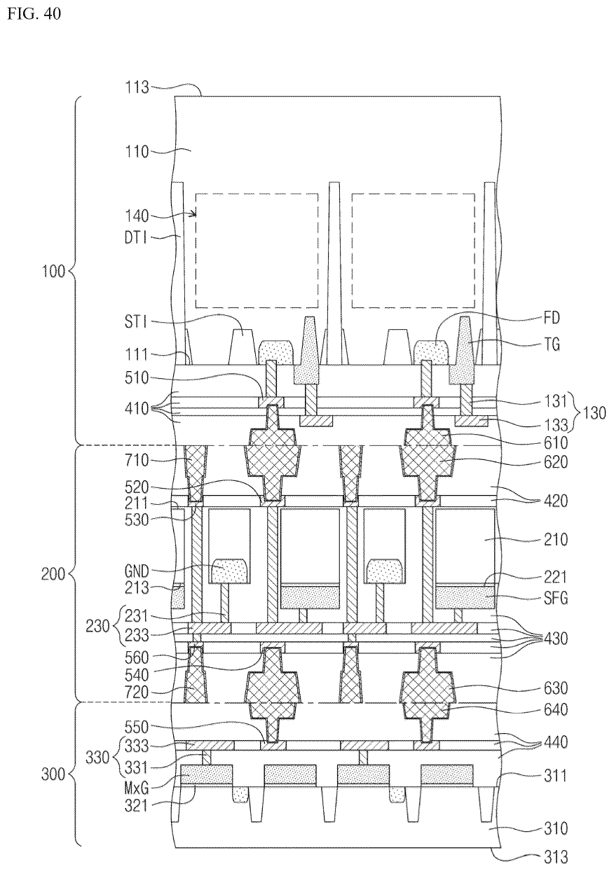

Referring to FIG. 40, the photoelectric conversion structure 100 and the intermediate structure 200 may be bonded to each other. The photoelectric conversion and second intermediate bonding pads 610 and 620 may be bonded to each other by a copper-copper bonding technique, and the photoelectric conversion and second intermediate interlayer dielectrics 410 and 420 may be covalently bonded.

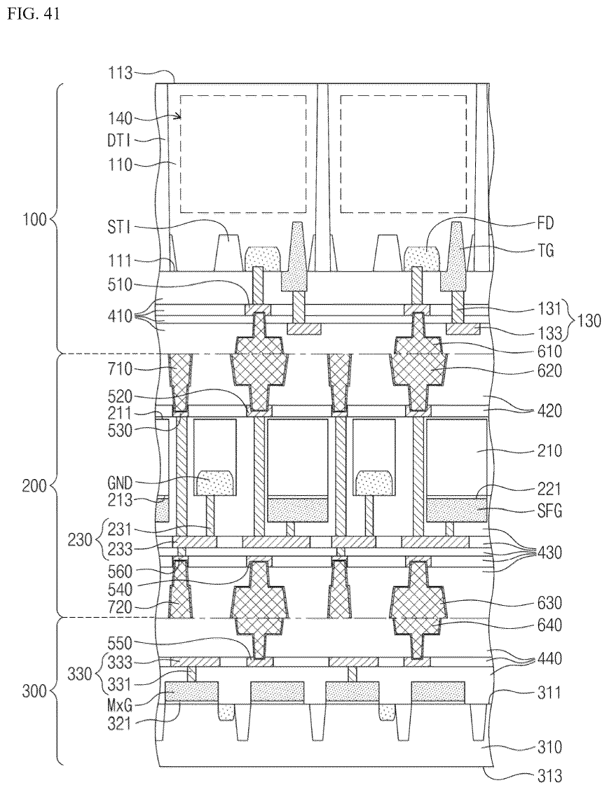

Referring to FIG. 41, the photoelectric conversion structure 100 may be processed. In one or more embodiments, a second surface 113 of the photoelectric conversion substrate 110 of the photoelectric conversion structure 100 may be etched or polished until the deep trench isolation pattern DTI is exposed.

Returning to FIG. 25, a substrate insulating layer, may be formed on the second surface 113 of the photoelectric conversion substrate 110. Color filters CF may be formed on the substrate insulating layer, and microlenses LS may be formed on the color filters CF.

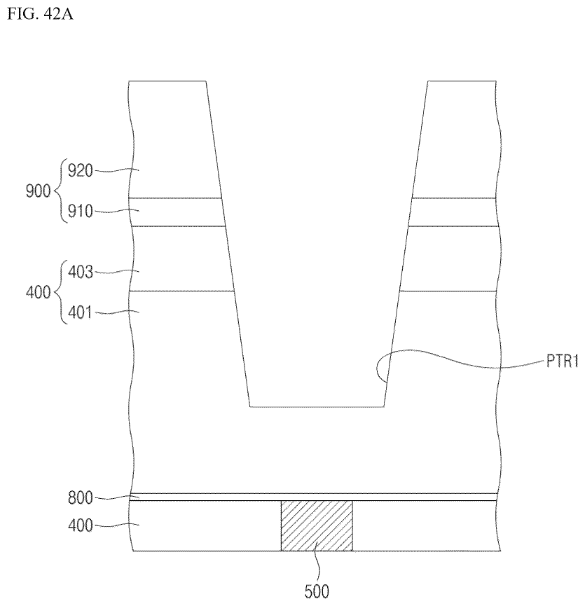

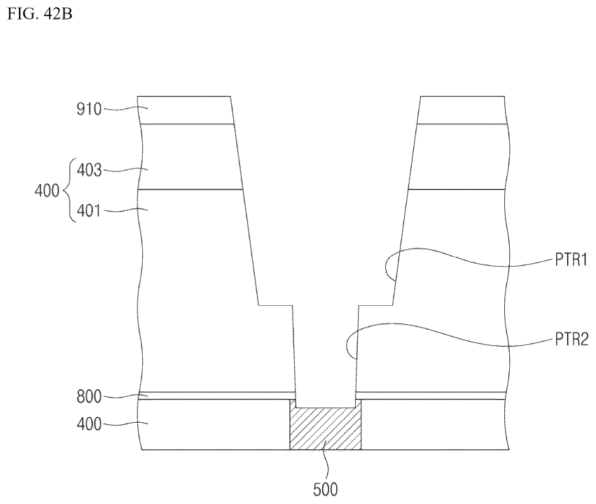

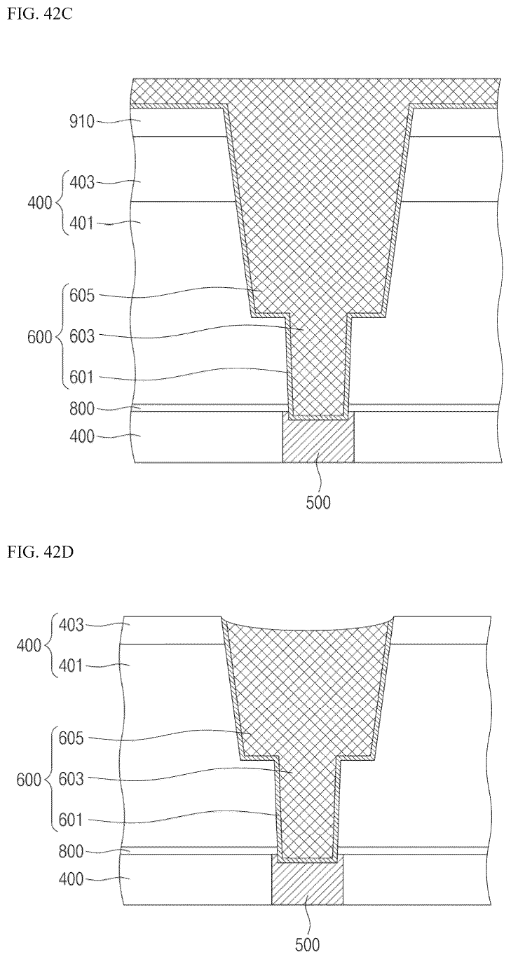

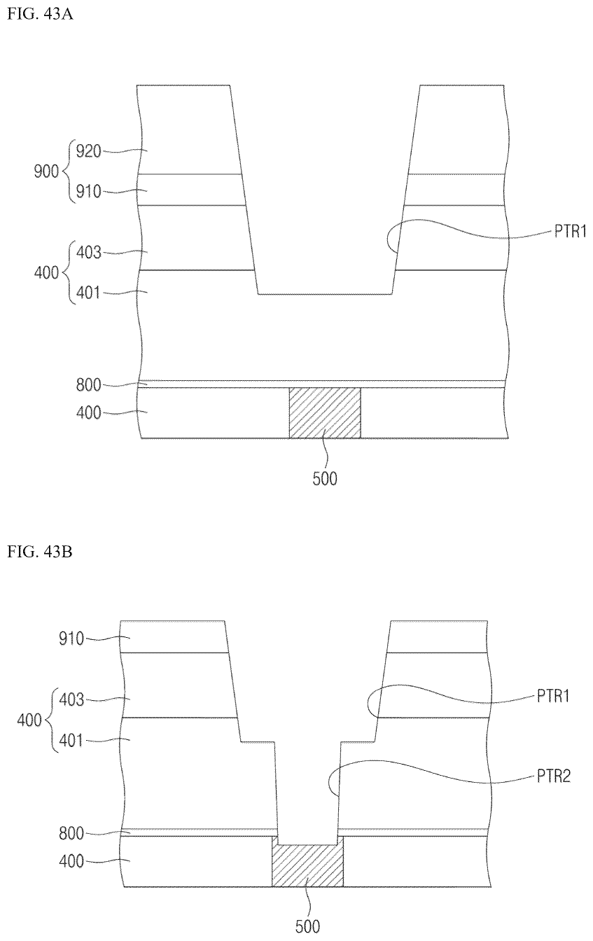

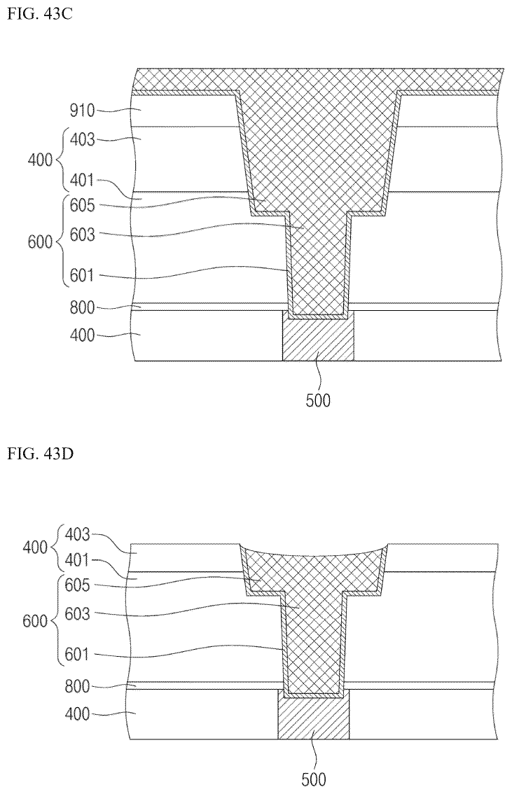

FIGS. 42A to 43D are cross-sectional views illustrating methods of manufacturing a bonding pad according to one or more embodiments. The method of FIGS. 42A to 42D according to one or more embodiments is a method of manufacturing a bonding pad having a relatively large thickness, and the method of FIGS. 43A to 43D is a method of manufacturing a bonding pad having a relatively small thickness. A thickness of each bonding pad according to one or more embodiments may be adjusted depending on whether a shield conductive pattern is present, through the illustrated method.

Referring to FIGS. 42A and 43A, an etch-stop layer 800 may be formed on an interlayer dielectric 400 including a terminal 500. In one or more embodiments, the interlayer dielectric 400 may include a body portion 401 and a capping portion 403, and the body portion 401 of the interlayer dielectric 400 may be formed on the etch-stop layer 800, and the capping portion 403 of the interlayer dielectric 400 may be formed on the body portion 401 of the interlayer dielectric 400. A sacrificial insulating layer 900 may be formed on the interlayer dielectric 400. In one or more embodiments, the sacrificial insulating layer 900 may include a hard mask layer 910 and a nitride layer 920 for a nitride floating cap (NFC). The hard mask layer 910 may be formed on the capping portion 403 of the interlayer dielectric 400, and the nitride layer 920 for an NFC may be formed on the hard mask layer 910. A first pad trench PTR1 may be formed in a portion of the interlayer dielectric 400 and in the sacrificial insulating layer 900. The first pad trench PTR1 may be formed in a portion of the body portion 401, the capping portion 403, the hard mask layer 910, and the nitride layer 920 for an NFC. The first pad trench PTR1 in the body portion 401 of FIG. 42A may be deeper than the first pad trench PTR1 in the body portion 401 of FIG. 43A.

Referring to FIGS. 42B and 43B, the nitride layer 920 for an NFC may be removed, and the body portion 401 exposed to the first pad trench PTR1 may be patterned to form a second pad trench PTR2. The second pad trench PTR2 may be formed to expose the terminal 500 through the body portion 401 below a bottom surface of the first pad trench PTR1 and the etch-stop layer 800. An upper surface of the terminal 500 exposed to the second pad trench PTR2 may be recessed by overetching.

Referring to FIGS. 42C and 43C, a conductive liner 601 may be conformally formed on an internal surface of the first pad trench PTR1, an internal surface of the second pad trench PTR2, and surfaces (for example, an upper surface and a side surface) of the hard mask layer 910. In one or more embodiments, the conductive liner 601 may serve as a seed layer and/or a diffusion barrier layer for electroplating.

A conductive layer may be formed on the conductive liner 601 to fill the first and second pad trenches PTR1 and PTR2. A portion of the conductive layer filling the second pad trench PTR2 may correspond to a pad via portion 603 of the bonding pad 600, and a portion of the conductive layer filling the first pad trench PTR1 may correspond to a pad portion 605 of the bonding pad 600. In one or more embodiments, the conductive layer may be formed using an electroplating process. The conductive liner 601 may be used as a seed layer. For example, the conductive layer may include copper.

Referring to FIGS. 42D and 43D, the conductive layer and the conductive liner 601 may be anisotropically etched until the capping portion 403 of the interlayer dielectric 400 is exposed, thereby forming the bonding pad 600. The anisotropic etching process may be performed using a chemical mechanical polishing (CMP) process and/or an etch-back process. In one or more embodiments, a portion of the capping portion 403 may be removed by the anisotropic etching process. As illustrated in FIGS. 42D and 43D, an upper surface of the pad portion 605 and an upper end of the conductive liner 601 may be recessed downward from an upper surface of the capping portion 403, but one or more embodiments are not limited thereto. In one or more embodiments, an upper surface of the pad portion 605 and the upper end of the conductive liner 601 may be substantially coplanar with an upper surface of the capping portion 403. Alternatively, the upper surface of the capping portion 403 may be lower than the upper surface of the pad portion 605 and the upper end of the conductive liner 601.

In one or more embodiments, at least one of the etch-stop layer 800 and the nitride layer 920 for an NFC may be omitted.

Unlike what is illustrated in FIGS. 42A to 43D, the second pad trench PTR2 may be formed to expose a floating diffusion region FD, a source follower gate SFG, or a ground region GND (see FIG. 14).

The method of manufacturing a bonding pad according to one or more embodiments may be applied to a method of manufacturing a shield conductive pattern according to one or more embodiments. In addition, the method of manufacturing the shield conductive pattern according to one or more embodiments may be performed simultaneously with the method of manufacturing the bonding pad.

As described above, according to one or more embodiments, shield conductive patterns may be selectively disposed in any one of the adjacent structures, and a width and/or a thickness of bonding pads of a structure that includes the shield conductive patterns may be increased or a width and/or a thickness of bonding pads of a structure that does not include the shield conductive patterns may be decreased. Accordingly, a pattern density of the bonding pads may be reduced to improve a conversion gain, an increase in parasitic capacitance caused by misalignment may be reduced or significantly reduced, and a change in bonding strength between the structures caused by the misalignment may be reduced. Thus, a conversion gain of a pixel may be increased, a decrease in the conversion gain of the pixel caused by misalignment may be significantly reduced, and bonding strength and device characteristic distribution in a wafer may be easily controlled. As a result, performance of an image sensor may be improved and degradation of the performance of the image sensor caused by misalignment may be significantly reduced.

As set forth above, according to one or more embodiments, a pattern density of bonding pads in an image sensor may be reduced, and a conversion gain of the image sensor may be improved.

While example embodiments have been shown and described above, it will be apparent to those skilled in the art that modifications and variations could be made without departing from the scope of the present disclosure as defined by the appended claims.

What is claimed is:

1. An image sensor comprising:
a first structure comprising:
a first terminal;
a first interlayer dielectric covering the first terminal; and
a first bonding pad within the first interlayer dielectric and electrically connected to the first terminal;
a second structure comprising:
a second terminal;
a second interlayer dielectric covering the second terminal; and
a second bonding pad within the second interlayer dielectric and electrically connected to the second terminal; and
a shield conductive pattern within one of the first interlayer dielectric and the second interlayer dielectric and electrically connected to a third terminal,
wherein the first bonding pad is bonded to the second bonding pad,
wherein the shield conductive pattern comprises a pattern surface facing another one of the first interlayer dielectric and the second interlayer dielectric, and
wherein an entirety of the pattern surface of the shield conductive pattern contacts the other one of the first interlayer dielectric and the second interlayer dielectric.

2. The image sensor of claim 1, wherein the first structure further comprises the third terminal,
wherein the shield conductive pattern is within the first interlayer dielectric, and
wherein the entirety of the pattern surface of the shield conductive pattern contacts the second interlayer dielectric.

3. The image sensor of claim 2, wherein the second bonding pad has a thickness that is smaller than a thickness of the first bonding pad.

4. The image sensor of claim 2, wherein the second bonding pad has a width that is smaller than a width of the first bonding pad.

5. The image sensor of claim 2, wherein the second interlayer dielectric comprises a body portion and a capping portion,
wherein the body portion comprises a first insulating material,
wherein the capping portion comprises a second insulating material, and
wherein the entirety of the pattern surface of the shield conductive pattern contacts the capping portion of the second interlayer dielectric.

6. The image sensor of claim 1, wherein the second structure further comprises the third terminal,
wherein the shield conductive pattern is within the second interlayer dielectric, and
wherein the entirety of the pattern surface of the shield conductive pattern contacts the first interlayer dielectric.

7. The image sensor of claim 6, wherein the first bonding pad has a thickness that is smaller than a thickness of the second bonding pad.

8. The image sensor of claim 6, wherein the first bonding pad has a width that is smaller than a width of the second bonding pad.

9. The image sensor of claim 6, wherein the first interlayer dielectric comprises a body portion and a capping portion,
wherein the body portion comprises a first insulating material,
wherein the capping portion comprises a second insulating material, and
wherein the entirety of the pattern surface of the shield conductive pattern contacts the capping portion of the first interlayer dielectric.

10. The image sensor of claim 1, further comprising:
a first substrate comprising pixel regions, a first surface, and a second surface opposite the first surface, the first interlayer dielectric covering the first surface of the first substrate;
photoelectric conversion regions in the pixel regions;
floating diffusion regions in the pixel regions;
a second substrate comprising a third surface and a fourth surface opposite the third surface, the third surface facing the first surface of the first substrate and the second interlayer dielectric covering the third surface of the second substrate;
a source follower gate on one of the third surface and the fourth surface; and
a ground region in one of the first substrate and the second substrate,
wherein the first terminal is electrically connected to or is at least one of the floating diffusion regions,
wherein the second terminal is electrically connected to or is the source follower gate, and
wherein the third terminal is electrically connected to or is the ground region.

11. The image sensor of claim 10, wherein the first bonding pad, the second bonding pad, and the shield conductive pattern vertically overlap the pixel regions.

12. The image sensor of claim 1, wherein the second structure further comprises:
a fourth terminal;
a third interlayer dielectric covering the fourth terminal; and
a third bonding pad within the third interlayer dielectric and electrically connected to the fourth terminal,
wherein the image sensor further comprises:
a third structure comprising:
a fifth terminal;
a fourth interlayer dielectric covering the fifth terminal; and
a fourth bonding pad within the fourth interlayer dielectric and electrically connected to the fifth terminal; and
an additional shield conductive pattern within one of the third interlayer dielectric and the fourth interlayer dielectric and electrically connected to a sixth terminal,
wherein the third bonding pad is bonded to the fourth bonding pad,
wherein the additional shield conductive pattern comprises a pattern surface facing another one of the third interlayer dielectric and the fourth interlayer dielectric, and
wherein an entirety of the pattern surface of the additional shield conductive pattern is in contact with the other one of the third interlayer dielectric and the fourth interlayer dielectric.

13. An image sensor comprising:
an intermediate structure comprising:
a first intermediate terminal;
a first intermediate interlayer dielectric covering the first intermediate terminal; and
a first intermediate bonding pad within the first intermediate interlayer dielectric and electrically connected to the first intermediate terminal;
a peripheral circuit structure comprising:
a peripheral circuit terminal;
a peripheral circuit interlayer dielectric covering the peripheral circuit terminal; and
a peripheral circuit bonding pad within the peripheral circuit interlayer dielectric and electrically connected to the peripheral circuit terminal; and
a lower shield conductive pattern within one of the first intermediate interlayer dielectric and the peripheral circuit interlayer dielectric and electrically connected to a lower shield terminal,
wherein the first intermediate bonding pad is bonded to the peripheral circuit bonding pad,
wherein the lower shield conductive pattern comprises a pattern surface facing another one of the first intermediate interlayer dielectric and the peripheral circuit interlayer dielectric, and
wherein an entirety of the pattern surface of the lower shield conductive pattern contacts the other one of the first intermediate interlayer dielectric and the peripheral circuit interlayer dielectric.

14. The image sensor of claim 13, further comprising:
an intermediate substrate comprising pixel regions, one surface, and an opposite surface opposite to the one surface, the first intermediate interlayer dielectric covering the opposite surface of the intermediate substrate;
a peripheral circuit substrate comprising one surface facing the opposite surface of the intermediate substrate, the peripheral circuit interlayer dielectric covering the one surface of the peripheral circuit substrate; and
a ground region in one of the intermediate substrate and the peripheral circuit substrate,
wherein the lower shield terminal is electrically connected to or is the ground region.

15. The image sensor of claim 13, wherein the intermediate structure comprises the lower shield terminal,
wherein the lower shield conductive pattern is within the first intermediate interlayer dielectric, and
wherein the entirety of the pattern surface of the lower shield conductive pattern contacts the peripheral circuit interlayer dielectric.

16. The image sensor of claim 13, wherein the peripheral circuit structure comprises the lower shield terminal,
wherein the lower shield conductive pattern is within the peripheral circuit interlayer dielectric, and
wherein the entirety of the pattern surface of the lower shield conductive pattern contacts the first intermediate interlayer dielectric.

17. The image sensor of claim 13, wherein the intermediate structure further comprises:
a second intermediate terminal;
a second intermediate interlayer dielectric covering the second intermediate terminal; and
a second intermediate bonding pad within the second intermediate interlayer dielectric and electrically connected to the second intermediate terminal,
wherein the image sensor further comprises:
a photoelectric conversion structure comprising:
a photoelectric conversion terminal;
a photoelectric conversion interlayer dielectric covering the photoelectric conversion terminal; and
a photoelectric conversion bonding pad within the photoelectric conversion interlayer dielectric and electrically connected to the photoelectric conversion terminal; and
an upper shield conductive pattern within one of the photoelectric conversion interlayer dielectric and the second intermediate interlayer dielectric,
wherein the photoelectric conversion bonding pad is bonded to the second intermediate bonding pad,
wherein the upper shield conductive pattern is electrically connected to an upper shield terminal and comprises a pattern surface facing another of the photoelectric conversion interlayer dielectric and the second intermediate interlayer dielectric, and
wherein an entirety of the pattern surface of the upper shield conductive pattern contacts the other one of the photoelectric conversion interlayer dielectric and the second intermediate interlayer dielectric.

18. An image sensor comprising:
a first structure comprising:
a first terminal;
a first interlayer dielectric covering the first terminal; and
a first bonding pad within the first interlayer dielectric and electrically connected to the first terminal;
a second structure comprising:
a second terminal;
a second interlayer dielectric covering the second terminal;
a second bonding pad within the second interlayer dielectric and electrically connected to the second terminal;
a third interlayer dielectric; and
a third bonding pad within the third interlayer dielectric;
a third structure comprising a fourth interlayer dielectric and a fourth bonding pad within the fourth interlayer dielectric; and
a shield conductive pattern within one of the first interlayer dielectric and the second interlayer dielectric and electrically connected to a third terminal,
wherein the first bonding pad is bonded to the second bonding pad,
wherein the third bonding pad is bonded to the fourth bonding pad,
wherein the shield conductive pattern comprises a pattern surface facing another one of the first interlayer dielectric and the second interlayer dielectric, and
wherein an entirety of the pattern surface of the shield conductive pattern contacts the other one of the first interlayer dielectric and the second interlayer dielectric.

19. The image sensor of claim 18, wherein one of the first bonding pad and the second bonding pad has a thickness that is larger than a thickness of another one of the first bonding pad and the second bonding pad, and
wherein the one of the first bonding pad and the second bonding pad and the shield conductive pattern are within the one of the first interlayer dielectric and the second interlayer dielectric.

20. The image sensor of claim 18, wherein one of the first bonding pad and the second bonding pad has a width that is larger than a thickness of another one of the first bonding pad and the second bonding pad, and
wherein the one of the first bonding pad and the second bonding pad and the shield conductive pattern are within the one of the first interlayer dielectric and the second interlayer dielectric.
